(19) United States
(12) Patent Application Publication
(10) Pub. No.: US 2026/0223396 A1
(43) Pub. Date: Jul. 30, 2026

(54) SEMICONDUCTOR DEVICE

(71) Applicant: ROHM CO., LTD., Kyoto-shi (JP)

(72) Inventors: Rogosu WAGURI, Kyoto-shi (JP); Seigo MORI, Kyoto-shi (JP)

(73) Assignee: ROHM CO., LTD., Kyoto-shi (JP)

(21) Appl. No.: 19/630,488

(22) Filed: Mar. 27, 2026

Related U.S. Application Data
(63) Continuation of application No. PCT/JP2024/033448, filed on Sep. 19, 2024.

(30) Foreign Application Priority Data
Oct. 5, 2023 (JP) 2023-173818

(51) Int. Cl. H10D 30/66; H10D 62/10; H10D 62/832; H10D 64/23

(52) U.S. Cl. CPC H10D 30/668; H10D 30/665; H10D 62/107; H10D 62/127; H10D 62/8325; H10D 64/2527

(57) ABSTRACT

A semiconductor device includes a chip having a principal surface, a semiconductor region of a first conductivity type formed in a surface layer portion of the principal surface, and a device structure having a source structure formed in the semiconductor region at an inner portion of the principal surface. A peripheral edge source electrode portion having a first outer edge is arranged on a peripheral edge portion of the principal surface and electrically connected to the source structure. A terminal region of a second conductivity type is formed in the semiconductor region at the peripheral edge portion and electrically connected to the peripheral edge source electrode portion. The terminal region includes a second outer edge positioned closer to a peripheral edge of the principal surface than the first outer edge, wherein a distance between the first and second outer edges is not less than 10 μm.

### CROSS-REFERENCE TO RELATED APPLICATIONS

The present application is a bypass continuation application of International Patent Application No. PCT/JP 2024/033448, filed on Sep. 19, 2024, which corresponds to Japanese Patent Application No. 2023-173818, filed on Oct. 5, 2023 with the Japan Patent Office, and the entire disclosure of the application is incorporated herein by reference.

### TECHNICAL FIELD

The present disclosure relates to a semiconductor device.

### BACKGROUND ART

Patent Literature 1 (US Patent Application Publication No. 2008/0277669) discloses a semiconductor device having a terminal structure in an outer peripheral region of a drift layer.

### BRIEF DESCRIPTION OF DRAWINGS

FIG. 1 is a plan view showing a semiconductor device according to a preferred embodiment of the present disclosure.

FIG. 2 is a sectional view taken along line II-II shown in FIG. 1.

FIG. 3 is a sectional view taken along line III-III shown in FIG. 1.

FIG. 4 is a plan view showing a layout example of a first principal surface.

FIG. 5 is an enlarged view of a portion surrounded by an alternate long and short dashed line V in FIG. 4.

FIG. 6 is a sectional view taken along line VI-VI shown in FIG. 5.

FIG. 7 is a sectional view taken along line VII-VII shown in FIG. 5.

FIG. 8 is an enlarged view of a portion surrounded by an alternate long and short dashed line VIII in FIG. 4.

FIG. 9 is a sectional view taken along line IX-IX shown in FIG. 8.

FIG. 10 is a sectional view taken along line X-X shown in FIG. 8.

FIG. 11 is a sectional view taken along line XI-XI shown in FIG. 8.

FIG. 12 is a sectional view taken along line XII-XII shown in FIG. 8.

FIG. 13 is an enlarged view of a portion surrounded by an alternate long and short dashed line XIII in FIG. 4.

FIG. 14 is a sectional view taken along line XIV-XIV shown in FIG. 13.

FIG. 15 is an enlarged view of a portion surrounded by an alternate long and short dashed line XV in FIG. 4.

FIG. 16 is a sectional view taken along line XVI-XVI shown in FIG. 15.

FIG. 17 is a sectional view showing a sectional structure taken along line XVII-XVII shown in FIG. 1 together with the outer peripheral structure according to a first configuration example.

FIG. 18 is a sectional view taken along line XVIII-XVIII shown in FIG. 1.

FIG. 19 is an enlarged view of a portion surrounded by an alternate long and short dashed line XIX in FIG. 17.

FIG. 20 is a plan view showing a layout example of principal electrodes arranged on the first principal surface.

FIG. 21 is a plan view showing a layout example of a second inorganic film.

FIG. 22 is a sectional view showing a sectional structure of the semiconductor device together with an outer peripheral structure according to a second configuration example, and is a view corresponding to FIG. 19.

FIG. 23 is a sectional view of a semiconductor device according to a reference embodiment, and is a view corresponding to FIG. 19.

FIG. 24 is a sectional view of a semiconductor device according to another preferred embodiment of the present disclosure, and is a view corresponding to FIG. 19.

### DESCRIPTION OF EMBODIMENTS

Hereinafter, specific embodiments shall be described in detail with reference to attached drawings. The attached drawings are all schematic views and are not strictly illustrated, and relative positional relationships, scales, proportions, angles etc., thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “n-type” may be referred to as a “first conductivity type” and the “p-type” may be referred to as a “second conductivity type.” The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

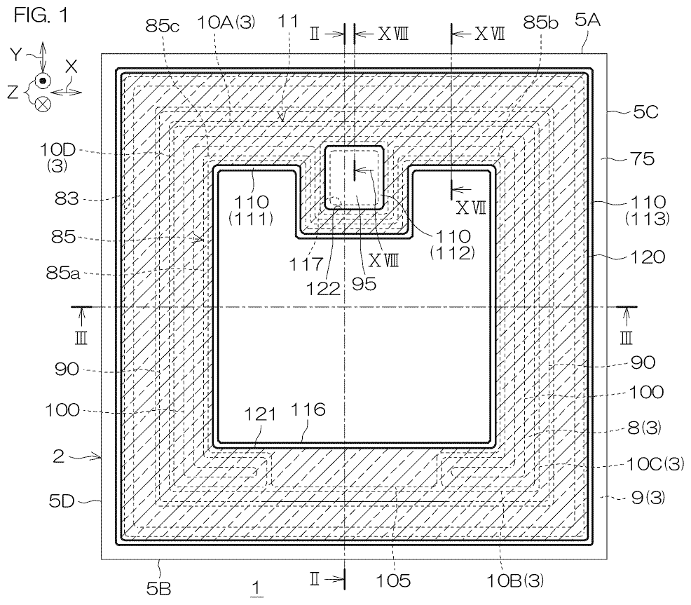

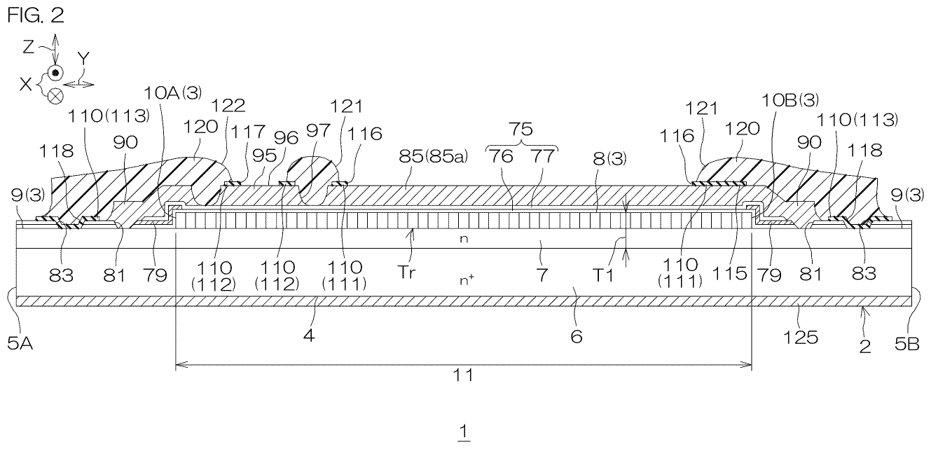

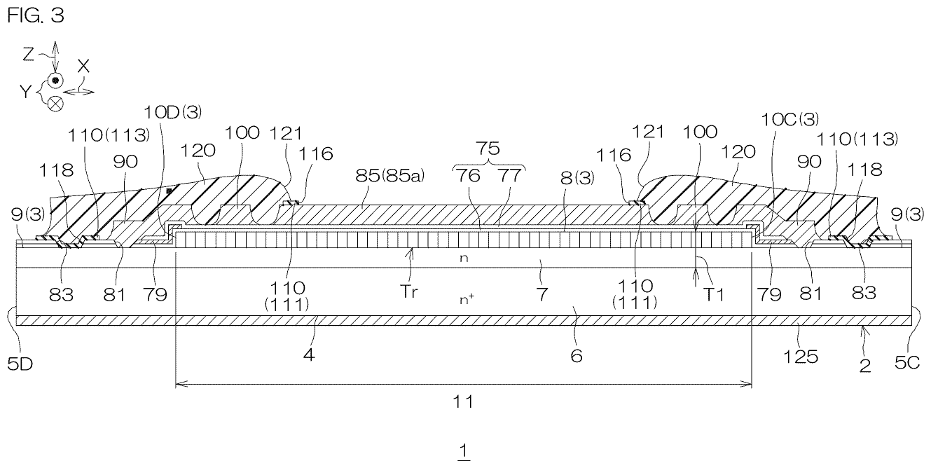

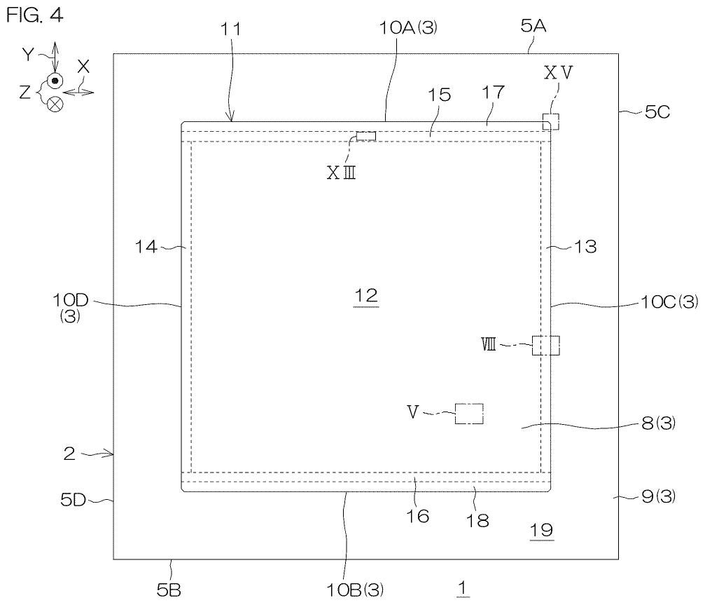

FIG. 1 is a plan view showing a semiconductor device 1 according to a preferred embodiment of the present disclosure. FIG. 2 is a sectional view taken along line II-II shown in FIG. 1. FIG. 3 is a sectional view taken along line III-III shown in FIG. 1. The semiconductor device 1 is a semiconductor switching device including a transistor structure (device structure) Tr of an insulated gate type. The transistor structure Tr may be referred to as a MISFET structure (Metal Insulator Semiconductor Field Effect Transistor structure). FIG. 4 is a plan view showing a layout example of a first principal surface 3.

Referring to FIGS. 1 to 3, the semiconductor device 1 includes a single crystal of a wide band gap semiconductor. In this preferred embodiment, the wide band gap semiconductor includes a chip 2 formed in a hexahedron shape (specifically, a rectangular parallelepiped shape). The semiconductor device 1 is a “wide bandgap semiconductor device.” The chip 2 may also be referred to as a “semiconductor chip” or a “wide bandgap semiconductor chip,” etc.

The wide bandgap semiconductor is a semiconductor that has a bandgap exceeding a bandgap of Si (silicon). GaN (gallium nitride), SiC (silicon carbide), C (diamond), etc., can be given as examples of the wide bandgap semiconductor. In this preferred embodiment, the chip 2 is an “SiC chip” that includes, as an example of the wide bandgap semiconductor, an SiC monocrystal that is a hexagonal crystal. The semiconductor device 1 is an “SiC semiconductor device.”

The semiconductor device 1 may also be referred to as an “SiC-MISFET.” The SiC monocrystal that is a hexagonal crystal has multiple polytypes including a 2H (hexagonal)-SiC monocrystal, a 4H-SiC monocrystal, a 6H-SiC monocrystal, etc. In this preferred embodiment, an example in which the chip 2 includes the 4H-SiC monocrystal is given, but the chip 2 may include another polytype instead.

Referring to FIGS. 1 to 3, the chip 2 has a first principal surface (principal surface) 3 on one side, a second principal surface 4 on the other side, and first to fourth side surfaces 5A to 5D connecting the first principal surface 3 and the second principal surface 4. In plan view as viewed from a vertical direction Z (hereinafter referred to simply as “plan view”), the first principal surface 3 and the second principal surface 4 are formed in quadrangle shapes. The vertical direction Z coincides with the thickness direction of the chip 2.

The first principal surface 3 and the second principal surface 4 are preferably formed by c-planes of the SiC monocrystal. In this case, preferably, the first principal surface 3 is formed by a silicon plane (a (0001) plane) of the SiC monocrystal and the second principal surface 4 is formed by a carbon plane (a (000-1) plane) of the SiC monocrystal.

The first side surface 5A and the second side surface 5B extend in a first direction X along the first principal surface 3 and are opposed in a second direction Y that intersects the first direction X along the first principal surface 3. Specifically, the second direction Y is orthogonal to the first direction X. The third side surface 5C and the fourth side surface 5D extend in the second direction Y and are opposed in the first direction X.

In this preferred embodiment, the first direction X is an a-axis direction (a [11-20] direction) of the SiC monocrystal and the second direction Y is an m-axis direction (a [1-100] direction) of the SiC monocrystal. As a matter of course, the first direction X may be the m-axis direction of the SiC monocrystal and the second direction Y may be the a-axis direction of the SiC monocrystal instead. In the following, directions extending along the first principal surface 3 are expressed at times as “horizontal directions.” The horizontal directions are also an XY plane (horizontal plane) formed by the first direction X and the second direction Y and are orthogonal to the vertical direction Z. The first principal surface 3 and the second principal surface 4 have an off angle inclined at a predetermined angle in a predetermined off direction with respect to the c-plane. The c-axis ((0001) axis) of the SiC monocrystal is inclined from the vertical line along the vertical direction Z in the off direction by an off angle. Also, the c-plane of the SiC monocrystal is inclined by just the off angle with respect to the horizontal plane. The off direction is preferably the a-axis direction (the first direction X) of the SiC monocrystal. The off angle may exceed 0° but be not more than 10°.

Referring to FIGS. 2 and 3, the semiconductor device 1 includes a first semiconductor region 6 of the n-type formed in a surface layer portion of the second principal surface 4 of the chip 2. A drain potential is applied as a first potential (a high potential) to the first semiconductor region 6. The first semiconductor region 6 extends in a layer shape along the second principal surface 4 and is exposed from the second principal surface 4 and the first to fourth side surfaces 5A to 5D. In this preferred embodiment, the first semiconductor region 6 is constituted of a semiconductor layer of the n-type. Specifically, the first semiconductor region 6 is constituted of a substrate (an SiC substrate) containing the SiC monocrystal (a semiconductor monocrystal). The first semiconductor region 6 forms the second principal surface 4 of the chip 2 and the first to fourth side surfaces 5A to 5D of the chip 2. The first semiconductor region 6 (the substrate) has the off direction and the off angle described above. The first semiconductor region 6 may have a thickness of not less than 10 μm and not more than 500 μm.

The semiconductor device 1 includes a second semiconductor region (semiconductor region) 7 of the n-type formed in a surface layer portion of the first principal surface 3. The second semiconductor region 7 may be referred to as a “semiconductor region,” a “semiconductor layer,” a “second semiconductor layer,” a “drift region,” etc. The second semiconductor region 7 has an n-type impurity concentration that is less than an n-type impurity concentration of the first semiconductor region 6. The second semiconductor region 7 is formed in a region at the first principal surface 3 side with respect to the first semiconductor region 6 in sectional view. The second semiconductor region 7 extends in a layer shape along the first principal surface 3 and is electrically connected to the first semiconductor region 6. The second semiconductor region 7 is exposed from the first principal surface 3 of the chip 2 and the first to fourth side surfaces 5A to 5D of the chip 2.

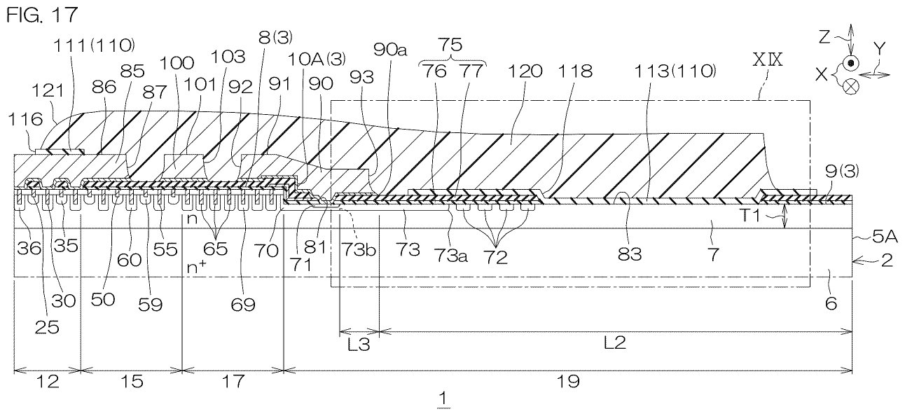

In this preferred embodiment, the second semiconductor region 7 is constituted of a semiconductor layer of the n-type. Specifically, the second semiconductor region 7 is constituted of an epitaxial layer (an SiC epitaxial layer) containing the SiC monocrystal (a semiconductor monocrystal). The second semiconductor region 7 (an epitaxial layer) forms the first principal surface 3 of the chip 2 and the first to fourth side surfaces 5A to 5D of the chip 2. The second semiconductor region 7 (the epitaxial layer) has the off direction and the off angle described above. The second semiconductor region 7 has a thickness T1 (see also FIGS. 17 to 19) less than the thickness of the first semiconductor region 6. The thickness T1 of the second semiconductor region 7 may be not less than 5 μm and not more than 15 μm. The thickness T1 of the second semiconductor region 7 may have a value belonging to at least one range among not less than 5 μm and not more than 7.5 μm, not less than 7.5 μm and not more than 10 μm, not less than 10 μm and not more than 12.5 μm, and not less than 12.5 μm and not more than 15 μm.

Referring to FIGS. 1 and 4, the semiconductor device 1 includes a first surface portion 8, a second surface portion 9, and first to fourth connecting surface portions 10A to 10D formed on the first principal surface 3. The first surface portion 8, the second surface portion 9, and the first to fourth connecting surface portions 10A to 10D demarcate a mesa 11 in the first principal surface 3.

The first surface portion 8 is formed at intervals inward from peripheral edges of the first principal surface 3 (from the first to fourth side surfaces 5A to 5D). The first surface portion 8 has a flat surface extending in the horizontal directions and is formed by a c-plane (an Si plane). In this preferred embodiment, the first surface portion 8 is formed in a polygonal shape (specifically, a quadrangle shape) having four sides parallel to the first to fourth side surfaces 5A to 5D in plan view.

The second surface portion 9 is positioned at a peripheral edge portion side of the first principal surface 3 with respect to the first surface portion 8 and is recessed in the thickness direction (to the second principal surface 4 side) of the chip 2 from a height position of the first surface portion 8. In plan view, the second surface portion 9 extends in a band shape along the first surface portion 8 and is formed in an annular shape (specifically, a quadrangle annular shape) surrounding the first surface portion 8. The second surface portion 9 is continuous to the first to fourth side surfaces 5A to 5D. The second surface portion 9 is formed substantially parallel to the first surface portion 8 and has a flat surface extending in the horizontal directions. In this preferred embodiment, the second surface portion 9 is formed by a c-plane (an Si plane).

The first to fourth connecting surface portions 10A to 10D extend in the vertical direction Z and are connected to the first surface portion 8 and the second surface portion 9. The first connecting surface portion 10A, the second connecting surface portion 10B, the third connecting surface portion 10C, and the fourth connecting surface portion 10D are positioned on the first side surface 5A side, the second side surface 5B side, the third side surface 5C side, and the fourth side surface 5D side, respectively. The first connecting surface portion 10A and the second connecting surface portion 10B extend in the first direction X and are opposed in the second direction Y. The third connecting surface portion 10C and the fourth connecting surface portion 10D extend in the second direction Y and are opposed in the first direction X.

The mesa 11 is demarcated in a projecting shape (a convex shape) in the first principal surface 3. The mesa 11 is formed just in the second semiconductor region 7 and is not formed in the first semiconductor region 6. The first to fourth connecting surface portions 10A to 10D may extend substantially perpendicularly between the first surface portion 8 and the second surface portion 9 and demarcate the mesa 11 of a quadrilateral prism shape. The first to fourth connecting surface portions 10A to 10D may be inclined obliquely downward from the first surface portion 8 toward the second surface portion 9 and demarcate the mesa 11 of a truncated quadrilateral prism shape.

The semiconductor device 1 includes an active region 12, a first end portion region 13, a second end portion region 14, a third end portion region 15, a fourth end portion region 16, a fifth end portion region 17, a sixth end portion region 18, and an outer peripheral region 19 in the first principal surface 3.

The active region 12 is a region including the transistor structure Tr. The active region 12 is a region where an output current (drain current) is generated. The active region 12 is provided in the inner portion of the first principal surface 3 at intervals from the peripheral edges of the first principal surface 3 (from the first to fourth connecting surface portions 10A to 10D). In this preferred embodiment, the active region 12 is provided in a polygonal shape (specifically, a quadrangle shape) having four sides parallel to the first to fourth side surfaces 5A to 5D in plan view. A ratio (an area ratio) of the planar area of the active region 12 to the planar area of the first principal surface 3 may be not less than 0.5 and not more than 0.95. The area ratio may have a value belonging to at least one range among not less than 0.5 and not more than 0.6, not less than 0.6 and not more than 0.7, not less than 0.7 and not more than 0.8, not less than 0.8 and not more than 0.9, and not less than 0.9 and not more than 0.95.

The first end portion region 13 is provided, in the first surface portion 8, at one side (the third connecting surface portion 10C side) in the first direction X with respect to the active region 12 and faces the active region 12 in the first direction X. In this preferred embodiment, the first end portion region 13 extends in a band shape in the second direction Y in plan view. The second end portion region 14 is provided, in the first surface portion 8, at the other side (the fourth connecting surface portion 10D side) in the first direction X with respect to the active region 12 and faces the first end portion region 13 in the first direction X with the active region 12 interposed therebetween. In this preferred embodiment, the second end portion region 14 extends in a band shape in the second direction Y in plan view.

The third end portion region 15 is provided at one side (the first connecting surface portion 10A side) in the second direction Y with respect to the active region 12 and faces the active region 12 in the second direction Y. In this preferred embodiment, the third end portion region 15 extends in the first direction X in plan view and faces the first end portion region 13 and the second end portion region 14 in the second direction Y. The fourth end portion region 16 is provided on the other side (the second connecting surface portion 10B side) in the second direction Y with respect to the active region 12, and faces the third end portion region 15 with the active region 12 interposed therebetween in the second direction Y. In this preferred embodiment, the fourth end portion region 16 extends in the first direction X in plan view and faces the first end portion region 13 and the second end portion region 14 in the second direction Y.

The fifth end portion region 17 is provided on one side (first connecting surface portion 10A side) in the second direction Y with respect to the third end portion region 15, and faces the active region 12 with the third end portion region 15 interposed therebetween in the second direction Y. The fifth end portion region 17 is provided in a region between the peripheral edge of the first surface portion 8 and the third end portion region 15. In this preferred embodiment, the fifth end portion region 17 extends in a band shape in the first direction X in plan view, and faces the first end portion region 13 and the second end portion region 14 with the third end portion region 15 interposed therebetween. The sixth end portion region 18 is provided on the other side (the second connecting surface portion 10B side) in the second direction Y with respect to the fourth end portion region 16, and faces the active region 12 with the fourth end portion region 16 interposed therebetween in the second direction Y. The sixth end portion region 18 is provided in a region between the peripheral edge of the first surface portion 8 and the fourth end portion region 16. In this preferred embodiment, the sixth end portion region 18 extends in a band shape in the first direction X in plan view, and faces the first end portion region 13 and the second end portion region 14 with the fourth end portion region 16 interposed therebetween.

The outer peripheral region 19 is provided as a non-active region in the second surface portion 9. In this preferred embodiment, the outer peripheral region 19 is provided in an annular shape (specifically, a quadrangle annular shape) surrounding the first surface portion 8 (the mesa 11) in plan view. The outer peripheral region 19 surrounds the active region 12, the first end portion region 13, the second end portion region 14, the third end portion region 15, the fourth end portion region 16, the fifth end portion region 17, and the sixth end portion region 18 in plan view.

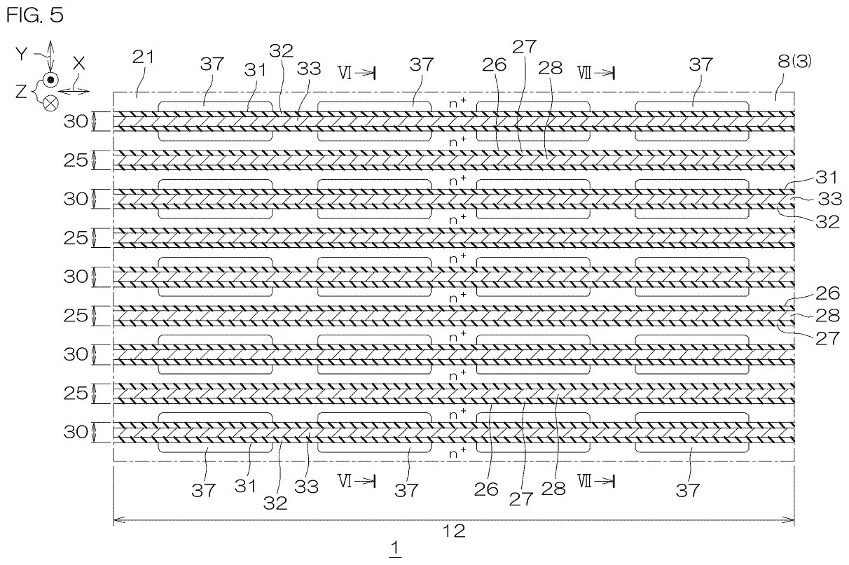

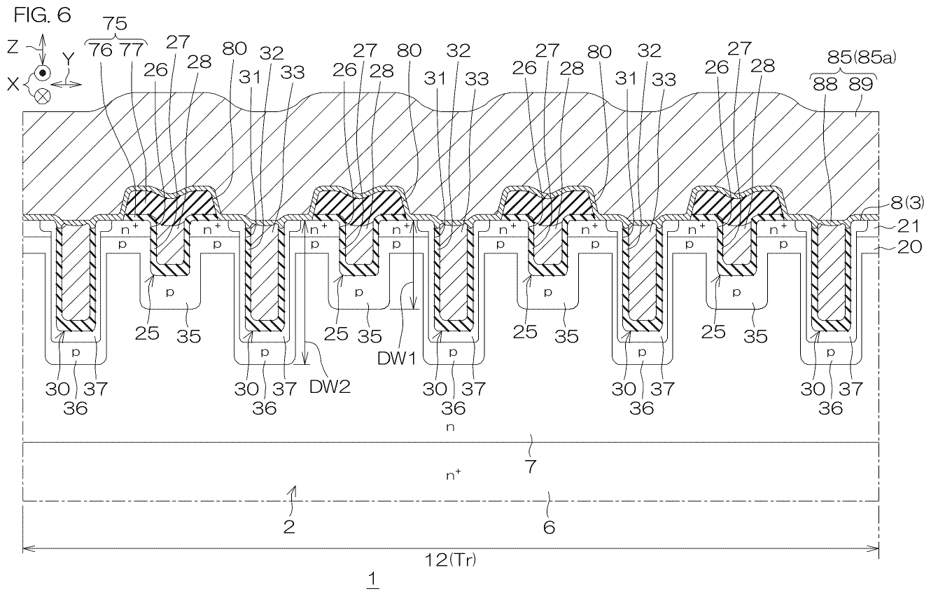

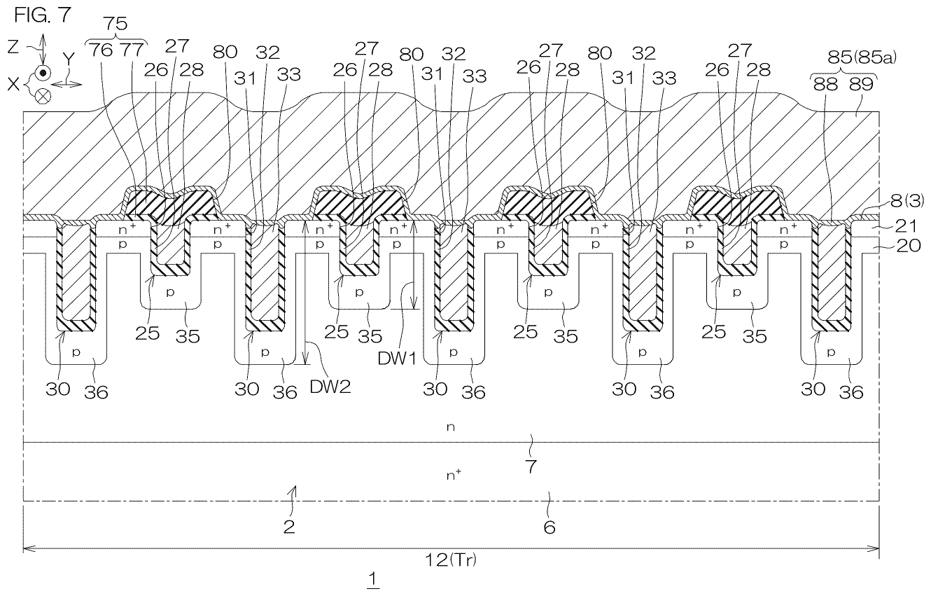

Hereinafter, the arrangement of the active region 12 shall be described. FIG. 5 is an enlarged view of a portion surrounded by an alternate long and short dashed line V in FIG. 4. FIG. 6 is a sectional view taken along line VI-VI shown in FIG. 5. FIG. 7 is a sectional view taken along line VII-VII shown in FIG. 5.

The semiconductor device 1 includes a body region 20 of the p-type formed in a surface layer portion of the first surface portion 8 (the first principal surface 3) in the active region 12. A source potential is applied as a second potential (low potential) differing from the first potential (high potential) to the body region 20. The source potential may be a reference potential serving as a reference of circuit operation. The reference potential may be a ground potential or a potential other than the ground potential.

The body region 20 is formed at an interval to the first principal surface 3 side from a bottom portion of the second semiconductor region 7 and faces the first semiconductor region 6 with a portion of the second semiconductor region 7 interposed therebetween. The body region 20 is formed at an interval to the first principal surface 3 side from a depth position of the second surface portion 9. The body region 20 extends in a layer shape along the first surface portion 8. In this preferred embodiment, the body region 20 is formed across an entirety of the first surface portion 8 and is exposed from the first to fourth connecting surface portions 10A to 10D.

The semiconductor device 1 includes a source region 21 of the n-type formed in a surface layer portion of the first surface portion 8 (the first principal surface 3) in the active region 12. The source potential is applied to the source region 21. The source region 21 has an n-type impurity concentration higher than the n-type impurity concentration of the second semiconductor region 7.

The source region 21 is formed in a surface layer portion of the body region 20. Specifically, the source region 21 is formed at an interval to the first principal surface 3 side from a bottom portion of the body region 20. The source region 21 is formed in a region at the first principal surface 3 side with respect to the body region 20. The source region 21 forms, together with the second semiconductor region 7, channels of the transistor inside the body region 20. In this preferred embodiment, the source region 21 is formed at intervals inward from the peripheral edges of the first surface portion 8.

The semiconductor device 1 includes a plurality of gate structures 25 of a trench type formed in the first surface portion 8 (the first principal surface 3) in the active region 12. A gate potential is applied as a control potential to the plurality of gate structures 25. The plurality of gate structures 25 control inversion and non-inversion of the channels inside the body region 20 in response to the gate potential.

The plurality of gate structures 25 are arranged in the first surface portion 8 at intervals inward from the peripheral edges of the first surface portion 8 (the first to fourth connecting surface portions 10A to 10D). As shown in FIG. 5, the plurality of gate structures 25 each extend in a band shape in the first direction X in plan view, and are arranged at intervals in the second direction Y. That is, in plan view, the plurality of gate structures 25 are aligned in a stripe shape extending in the first direction X.

As shown in FIGS. 6 and 7, the plurality of gate structures 25 penetrate the body region 20 and the source region 21 to reach the second semiconductor region 7. The body region 20 and the source region 21 are each positioned at both sides of the plurality of gate structures 25. The plurality of gate structures 25 are formed at intervals to the first surface portion 8 side from the bottom portion of the second semiconductor region 7 and face the first semiconductor region 6 with portions of the second semiconductor region 7 interposed therebetween.

Side walls of the plurality of gate structures 25 are each formed by an m-plane (a (1-100) plane) of the SiC monocrystal. As a matter of course, the side walls of the plurality of gate structures 25 may each be formed instead by an a-plane (a (11-20) plane) of the SiC monocrystal in accordance with the extension direction of the gate structures 25. The side walls of the plurality of gate structures 25 are formed substantially perpendicular to the first principal surface 3. Bottom walls of the plurality of gate structures 25 are formed by a c-plane (an Si plane) of the SiC monocrystal. The bottom walls of the plurality of gate structures 25 preferably extend substantially flatly in the horizontal direction. As a matter of course, the bottom walls of the plurality of gate structures 25 may instead be curved in arcuate shapes toward the second principal surface 4 side.

One gate structure 25 includes a first trench 26, a first insulating film 27, and a first embedded electrode 28. The first trench 26 is formed in the first surface portion 8 and demarcates wall surfaces (the side walls and the bottom wall) of the gate structure 25. The first insulating film 27 covers wall surfaces of the first trench 26. The first insulating film 27 may include at least one among a silicon oxide film, a silicon nitride film, and a silicon oxynitride film. The first insulating film 27 particularly preferably includes a silicon oxide film that is constituted of an oxide of the chip 2.

The first embedded electrode 28 is embedded in the first trench 26 with the first insulating film 27 interposed therebetween. The first embedded electrode 28 may contain either or both of a conductive polysilicon of the p-type and a conductive polysilicon of the n-type. The first embedded electrode 28 faces a channel with the first insulating film 27 interposed therebetween. The first embedded electrode 28 faces the second semiconductor region 7, the body region 20, and the source region 21 with the first insulating film 27 interposed therebetween.

The semiconductor device 1 includes a plurality of first source structures (source structures) 30 of the trench type formed in the first principal surface 3 (the first surface portion 8) in the active region 12. The source potential is applied to the plurality of first source structures 30.

The plurality of first source structures 30 are formed in the first surface portion 8 such as to be mutually adjacent to the plurality of gate structures 25 in the second direction Y in the active region 12. Specifically, the plurality of first source structures 30 are respectively arranged in regions between the plurality of gate structures 25 and face the plurality of gate structures 25 in the second direction Y. That is, the plurality of first source structures 30 are aligned alternately with the plurality of gate structures 25 in the second direction Y.

As shown in FIG. 5, each of the plurality of first source structures 30 extends in a band shape in the first direction X in plan view. In this preferred embodiment, the plurality of first source structures 30 are led out from the active region 12 to one or both of the first end portion region 13 and the second end portion region 14 (both in this preferred embodiment). The plurality of first source structures 30 face the gate structures 25 in the second direction Y in the active region 12 but do not face the gate structures 25 in the second direction Y in the first end portion region 13 (the second end portion region 14).

As shown in FIGS. 6 and 7, the plurality of first source structures 30 penetrate the body region 20 and the source region 21 to reach the second semiconductor region 7. That is, the body region 20 and the source region 21 are each positioned at both sides of the plurality of first source structures 30.

Side walls of the plurality of first source structures 30 are each formed by an m-plane of the SiC monocrystal. As a matter of course, the side walls of the plurality of first source structures 30 may each be formed instead by an a-plane of the SiC monocrystal in accordance with the extension direction of the first source structures 30. The side walls of the plurality of first source structures 30 are formed substantially perpendicular to the first principal surface 3. Bottom walls of the plurality of first source structures 30 are formed by a c-plane (an Si plane) of the SiC monocrystal. The bottom walls of the plurality of first source structures 30 preferably extend substantially flatly in the horizontal direction. As a matter of course, the bottom walls of the plurality of first source structures 30 may instead be curved in arcuate shapes toward the second principal surface 4 side.

The first source structure 30 preferably has a width greater than the width of the gate structure 25. The first source structure 30 preferably has a depth greater than the depth of the gate structure 25. The depth of the first source structure 30 is preferably substantially equal to the depth of the second surface portion 9.

As shown in FIGS. 6 and 7, one first source structure 30 includes a second trench 31, a second insulating film 32, and a second embedded electrode 33. The second trench 31 is formed in the first surface portion 8 and demarcates wall surfaces (the side walls and the bottom wall) of the first source structure 30. Side walls of the second trench 31 are connected to either or both (in this preferred embodiment, both) of the third connecting surface portion 10C and the fourth connecting surface portion 10D. A bottom wall of the second trench 31 is connected to the second surface portion 9.

The second insulating film 32 covers wall surfaces of the second trench 31. The second insulating film 32 may include at least one among a silicon oxide film, a silicon nitride film, and a silicon oxynitride film. The second insulating film 32 preferably includes the same type of insulating material as the insulating material of the first insulating film 27.

The second embedded electrode 33 is embedded in the second trench 31 with the second insulating film 32 interposed therebetween. The second embedded electrode 33 may contain either or both of a conductive polysilicon of the p-type and a conductive polysilicon of the n-type. The second embedded electrode 33 preferably contains the same type of conductive material as the conductive material of the first embedded electrode 28. The second embedded electrode 33 faces the second semiconductor region 7, the body region 20, and the source region 21 with the second insulating film 32 interposed therebetween.

Referring to FIGS. 5 to 7, the semiconductor device 1 includes a plurality of first well regions 35 of the p-type formed in a region along the plurality of gate structures 25 in the surface layer portion of the first surface portion 8 (the first principal surface 3) of the active region 12. The p-type impurity concentration of the first well region 35 is higher than the p-type impurity concentration of the body region 20.

The plurality of first well regions 35 are formed along the side walls and the bottom walls of the corresponding gate structures 25 and are each electrically connected to the body region 20 in the surface layer portion of the first surface portion 8. The plurality of first well regions 35 are formed at intervals to the first surface portion 8 side from the bottom portion of the second semiconductor region 7 and face the first semiconductor region 6 with portions of the second semiconductor region 7 interposed therebetween. The plurality of first well regions 35 form pn junction portions with the second semiconductor region 7.

Referring to FIGS. 5 to 7, the semiconductor device 1 includes a plurality of second well regions 36 of the p-type formed in a region along the plurality of first source structures 30 in the surface layer portion of the first surface portion 8 (the first principal surface 3) of the active region 12. The p-type impurity concentration of the second well region 36 is higher than the p-type impurity concentration of the body region 20. The plurality of second well regions 36 are respectively formed in a one-to-one correspondence with respect to the plurality of first source structures 30. The plurality of second well regions 36 are respectively formed in the regions along the corresponding first source structures 30 at intervals from the plurality of gate structures 25.

The plurality of second well regions 36 are formed along the side walls and the bottom walls of the corresponding first source structures 30 and are each electrically connected to the body region 20 in the surface layer portion of the first surface portion 8. The plurality of second well regions 36 extend along the wall surfaces of the corresponding first source structures 30 in the active region 12, the first end portion region 13, and the second end portion region 14 and are exposed from the third connecting surface portion 10C and the fourth connecting surface portion 10D.

The plurality of second well regions 36 are formed at intervals to the first surface portion 8 side from the bottom portion of the second semiconductor region 7 and face the first semiconductor region 6 with portions of the second semiconductor region 7 interposed therebetween. Bottom portions of the plurality of second well regions 36 are positioned to the bottom portion side of the second semiconductor region 7 with respect to depth positions of bottom portions of the plurality of first well regions 35. That is, a depth DW2 (a second depth, see FIGS. 6 and 7) of the second well region 36 is greater than a depth DW1 (see FIGS. 6 and 7) of the first well region 35. The plurality of second well regions 36 form pn junction portions with the second semiconductor region 7.

Referring to FIGS. 5 and 6, the semiconductor device 1 includes a plurality of contact regions 37 of the p-type formed in a region along the plurality of second well regions 36 in the surface layer portion of the first surface portion 8 (the first principal surface 3) of the active region 12. The contact regions 37 have a p-type impurity concentration higher than the p-type impurity concentration of the body region 20. The p-type impurity concentration of the contact regions 37 is higher than the p-type impurity concentration of the second well regions 36 (the first well regions 35).

The plurality of contact regions 37 are formed inside the plurality of second well regions 36. The plurality of contact regions 37 extend along the wall surfaces of the corresponding first source structures 30 inside the corresponding second well regions 36. The plurality of contact regions 37 are formed in a one-to-multiple correspondence with respect to the corresponding single first source structure 30.

The plurality of contact regions 37 are formed at intervals in the first direction X along the corresponding first source structure 30. The plurality of contact regions 37 are led out to a surface layer portion of the body region 20 along the wall surfaces of the corresponding first source structure 30 inside the corresponding second well region 36 and are exposed from the first surface portion 8.

In this preferred embodiment, the plurality of contact regions 37 each extend in a band shape in the first direction X in plan view. The plurality of contact regions 37 along the single first source structure 30 face, in the second direction Y, the plurality of contact regions 37 along another first source structure 30.

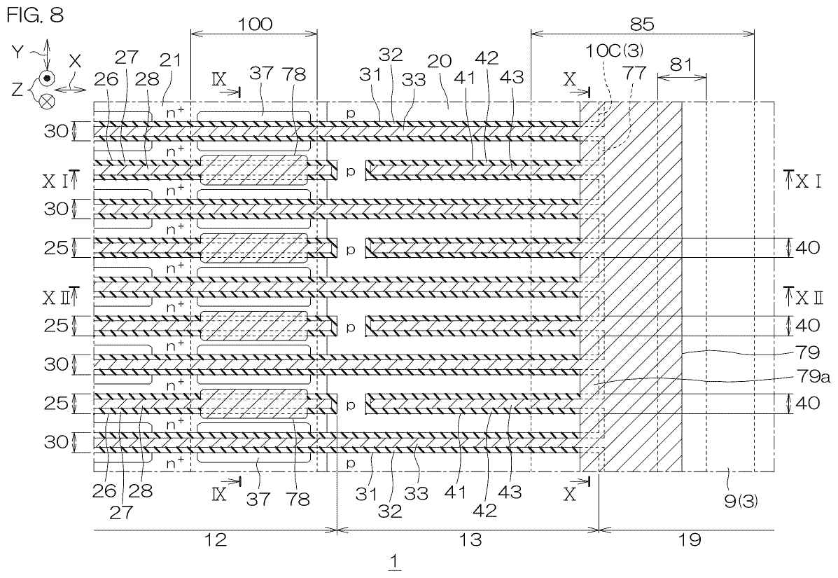

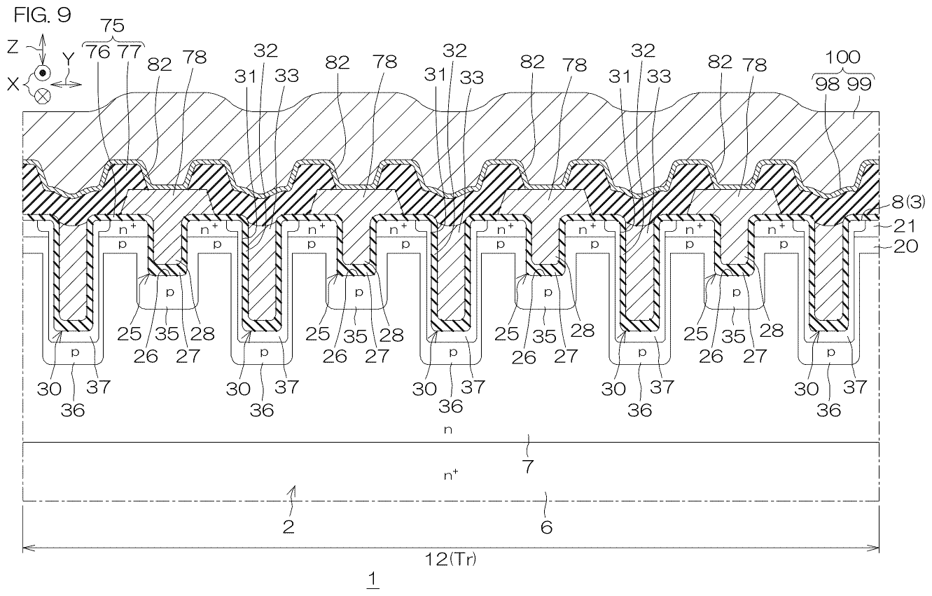

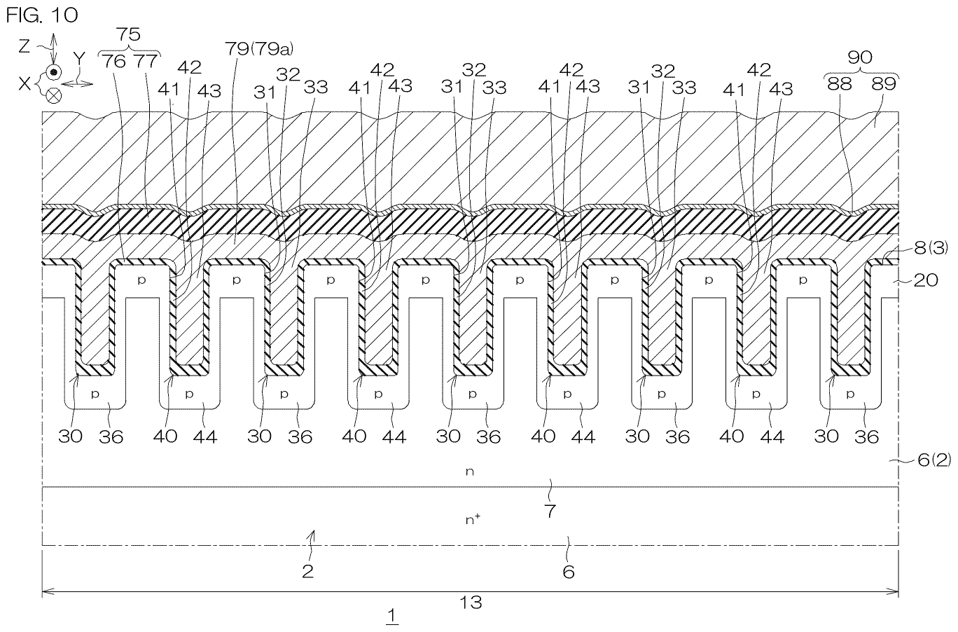

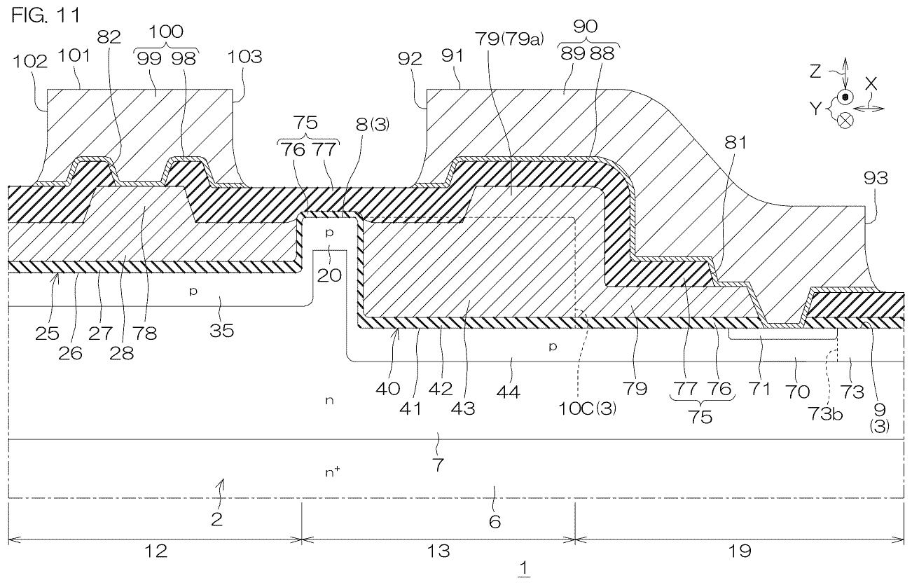

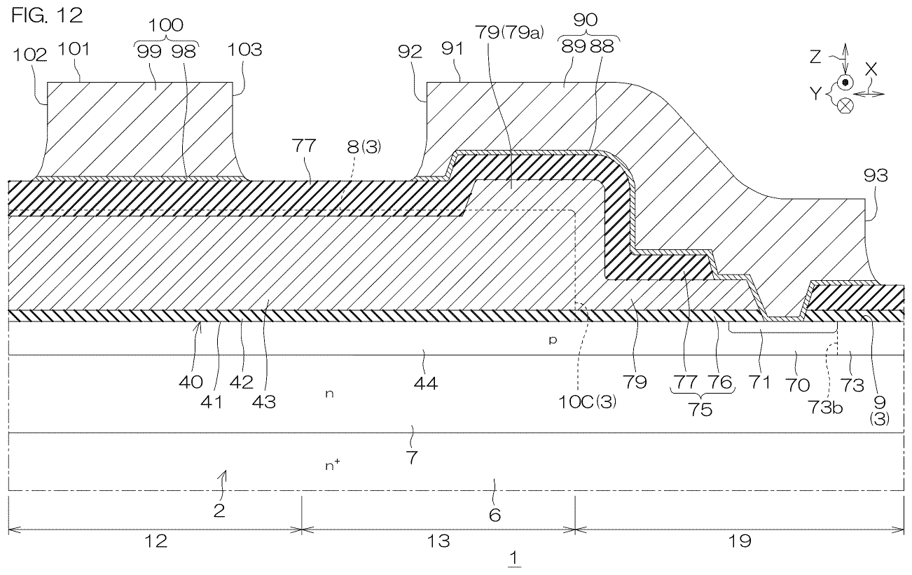

Hereinafter, the arrangement of the first end portion region 13 will be described. FIG. 8 is an enlarged view of a portion surrounded by an alternate long and short dashed line VIII in FIG. 4. FIG. 9 is a sectional view taken along line IX-IX shown in FIG. 8. FIG. 10 is a sectional view taken along line X-X shown in FIG. 8. FIG. 11 is a sectional view taken along line XI-XI shown in FIG. 8. FIG. 12 is a sectional view taken along line XII-XII shown in FIG. 8. Since the layout of the second end portion region 14 is similar to the layout of the first end portion region 13, the description of the layout of the second end portion region 14 will be omitted. The layout of the second end portion region 14 is obtained by replacing the “first end portion region 13” with the “second end portion region 14” and replacing the “third connecting surface portion 10C” with the “fourth connecting surface portion 10D” in the description of the first end portion region 13.

The semiconductor device 1 includes a plurality of second source structures 40 of the trench type formed in the first surface portion 8 (the first principal surface 3) in the first end portion region 13. The source potential is applied to the plurality of second source structures 40. The plurality of second source structures 40 are respectively arranged in regions between a peripheral edge of the first surface portion 8 (the third connecting surface portion 10C) and the plurality of gate structures 25. The plurality of second source structures 40 are respectively arranged in regions between the plurality of first source structures 30 and face the plurality of first source structures 30 in the second direction Y. The plurality of second source structures 40 are aligned alternately with the plurality of first source structures 30 in the second direction Y.

One second source structure 40 includes a third trench 41, a third insulating film 42, and a third embedded electrode 43. The third trench 41 is formed in the first surface portion 8 and demarcates wall surfaces (the side walls and the bottom wall) of the second source structure 40. Side walls of the third trench 41 are connected to the third connecting surface portion 10C. A bottom wall of the third trench 41 is connected to the second surface portion 9. The third insulating film 42 covers wall surfaces of the third trench 41. The third embedded electrode 43 is embedded in the third trench 41 with the third insulating film 42 interposed therebetween. The third embedded electrode 43 may contain either or both of a conductive polysilicon of the p-type and a conductive polysilicon of the n-type.

Referring to FIGS. 10 to 12, the semiconductor device 1 includes a plurality of third well regions 44 of the p-type formed in a region along the plurality of second source structures 40 in the surface layer portion of the first surface portion 8 (the first principal surface 3) of the first end portion region 13. The third well regions 44 have a p-type impurity concentration higher than the p-type impurity concentration of the body region 20.

The plurality of third well regions 44 are respectively formed in a one-to-one correspondence with respect to the plurality of second source structures 40. The plurality of third well regions 44 are respectively formed in the regions along the corresponding second source structures 40 at intervals from the plurality of first well regions 35 and the plurality of second well regions 36. The plurality of third well regions 44 are formed along the side walls and the bottom walls of the corresponding second source structures 40 and are each electrically connected to the body region 20 in the surface layer portion of the first surface portion 8. The plurality of third well regions 44 form pn junction portions with the second semiconductor region 7.

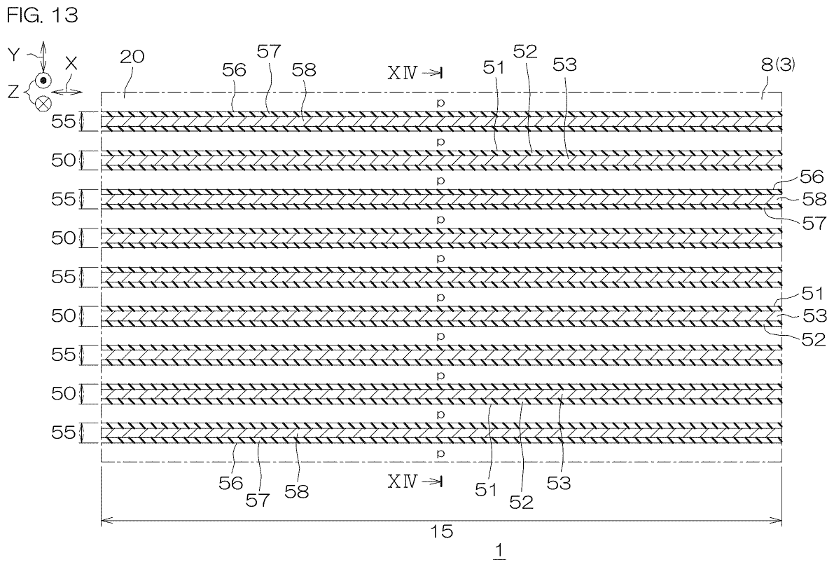

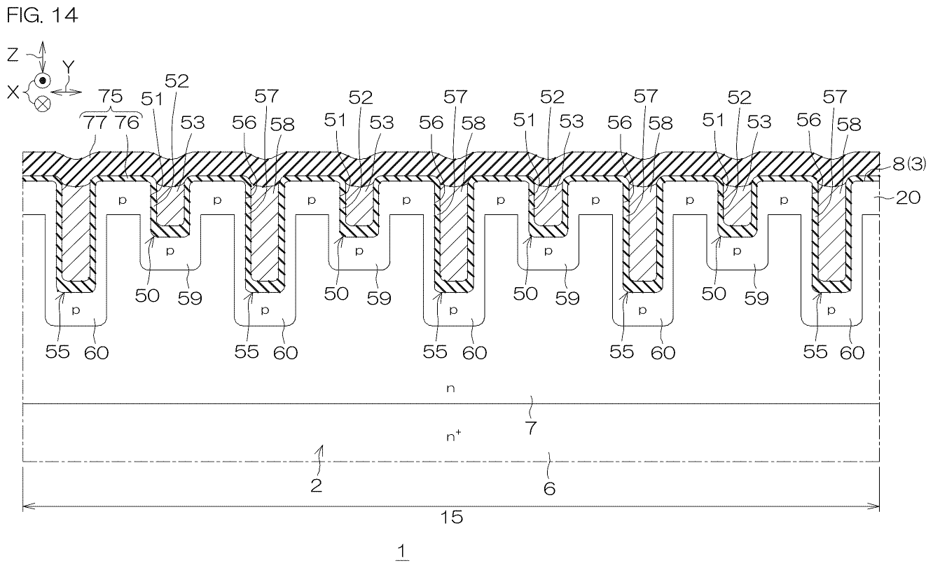

Hereinafter, the arrangement of the third end portion region 15 will be described. FIG. 13 is an enlarged view of a portion surrounded by an alternate long and short dashed line XIII in FIG. 4. FIG. 14 is a sectional view taken along line XIV-XIV shown in FIG. 13. Since the layout of the fourth end portion region 16 is similar to the layout of the third end portion region 15, the description of the layout of the fourth end portion region 16 will be omitted. The layout of the fourth end portion region 16 is obtained by replacing the “third end portion region 15” with the “fourth end portion region 16” and replacing the “first connecting surface portion 10A” with the “second connecting surface portion 10B” in the description of the third end portion region 15.

The semiconductor device 1 includes a plurality of dummy gate structures 50 of the trench type formed in the first surface portion 8 (the first principal surface 3) in the third end portion region 15. The source potential is applied to the plurality of dummy gate structures 50. The plurality of dummy gate structures 50 do not contribute to channel inversion and non-inversion.

The plurality of dummy gate structures 50 are formed in a region at the first connecting surface portion 10A side with respect to the active region 12. In plan view, the plurality of dummy gate structures 50 each extend in a band shape in the first direction X and are aligned at intervals in the second direction Y. In plan view, the plurality of dummy gate structures 50 are aligned in a stripe shape extending in the first direction X. The plurality of dummy gate structures 50 face the plurality of gate structures 25 and the plurality of first source structures 30 in the second direction Y.

One dummy gate structure 50 includes a fourth trench 51, a fourth insulating film 52, and a fourth embedded electrode 53. The fourth trench 51 is formed in the first surface portion 8 and demarcates wall surfaces (the side walls and the bottom wall) of the dummy gate structure 50. The fourth insulating film 52 covers wall surfaces of the fourth trench 51. The fourth embedded electrode 53 is embedded in the fourth trench 51 with the fourth insulating film 52 interposed therebetween. The fourth embedded electrode 53 may contain either or both of a conductive polysilicon of the p-type and a conductive polysilicon of the n-type.

The semiconductor device 1 includes a plurality of third source structures 55 of the trench type formed in the first surface portion 8 (the first principal surface 3) in the third end portion region 15. The source potential is applied to the plurality of third source structures 55.

The plurality of third source structures 55 are formed in a region to the first connecting surface portion 10A side with respect to the active region 12. The plurality of third source structures 55 are formed in the first surface portion 8 such as to be mutually adjacent to the plurality of dummy gate structures 50 in the second direction Y in the third end portion region 15. Specifically, the plurality of third source structures 55 are respectively arranged in regions between the plurality of dummy gate structures 50 and face the plurality of dummy gate structures 50 in the second direction Y. The plurality of third source structures 55 are alternately aligned with the plurality of dummy gate structures 50 in the second direction Y. The plurality of third source structures 55 each extend in a band shape in the first direction X in plan view. The plurality of third source structures 55 face the plurality of gate structures 25 and the plurality of first source structures 30 in the second direction Y.

One third source structure 55 includes a fifth trench 56, a fifth insulating film 57, and a fifth embedded electrode 58. The fifth trench 56 is formed in the first surface portion 8 and demarcates wall surfaces (the side walls and the bottom wall) of the third source structure 55. Side walls of the fifth trench 56 are connected to either or both (in this preferred embodiment, both) of the third connecting surface portion 10C and the fourth connecting surface portion 10D. A bottom wall of the fifth trench 56 is connected to the second surface portion 9.

The fifth insulating film 57 covers wall surfaces of the fifth trench 56. The fifth insulating film 57 may include at least one among a silicon oxide film, a silicon nitride film, and a silicon oxynitride film. The fifth embedded electrode 58 is embedded in the fifth trench 56 with the fifth insulating film 57 interposed therebetween. The fifth embedded electrode 58 may contain either or both of a conductive polysilicon of the p-type and a conductive polysilicon of the n-type.

As shown in FIG. 14, the semiconductor device 1 includes a plurality of p-type fourth well regions 59 formed in a region along the plurality of dummy gate structures 50 in the surface layer portion of the first surface portion 8 (the first principal surface 3) of the third end portion region 15. The fourth well regions 59 have a p-type impurity concentration higher than the p-type impurity concentration of the body region 20.

The plurality of fourth well regions 59 are respectively formed in a one-to-one correspondence with respect to the plurality of dummy gate structures 50. The plurality of fourth well regions 59 are respectively formed in the regions along the corresponding dummy gate structures 50 at intervals from the plurality of third source structures 55. The plurality of fourth well regions 59 are formed along the side walls and the bottom walls of the corresponding dummy gate structures 50 and are each electrically connected to the body region 20 in the surface layer portion of the first surface portion 8. The plurality of fourth well regions 59 form pn junction portions with the second semiconductor region 7.

As shown in FIG. 14, the semiconductor device 1 includes a plurality of p-type fifth well regions 60 formed in a region along the plurality of third source structures 55 in the surface layer portion of the first surface portion 8 (first principal surface 3) of the third end portion region 15. The fifth well regions 60 have a p-type impurity concentration higher than the p-type impurity concentration of the body region 20.

The plurality of fifth well regions 60 are respectively formed in a one-to-one correspondence with respect to the plurality of third source structures 55. The plurality of fifth well regions 60 are respectively formed in the regions along the corresponding third source structures 55 at intervals from the plurality of dummy gate structures 50. The plurality of fifth well regions 60 are formed along the side walls and the bottom walls of the corresponding third source structures 55 and are each electrically connected to the body region 20 in the surface layer portion of the first surface portion 8. The plurality of fifth well regions 60 form pn junction portions with the second semiconductor region 7.

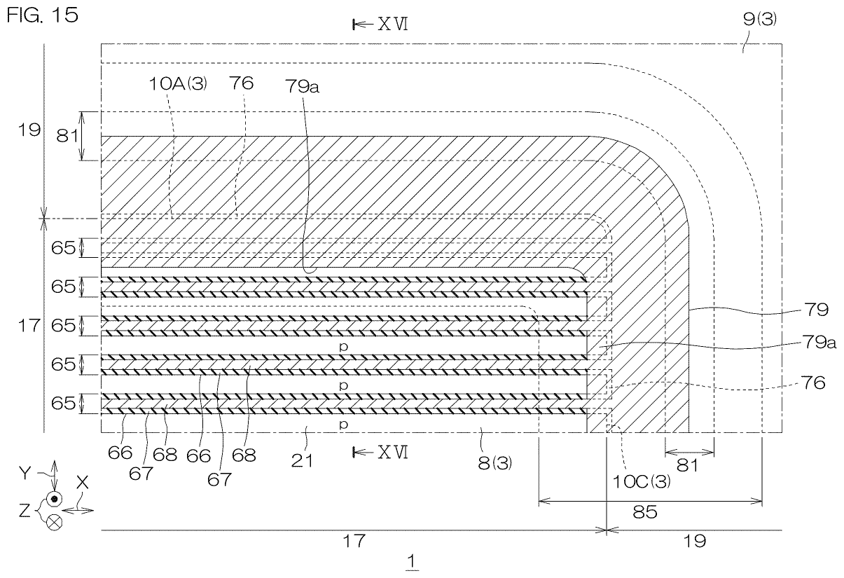

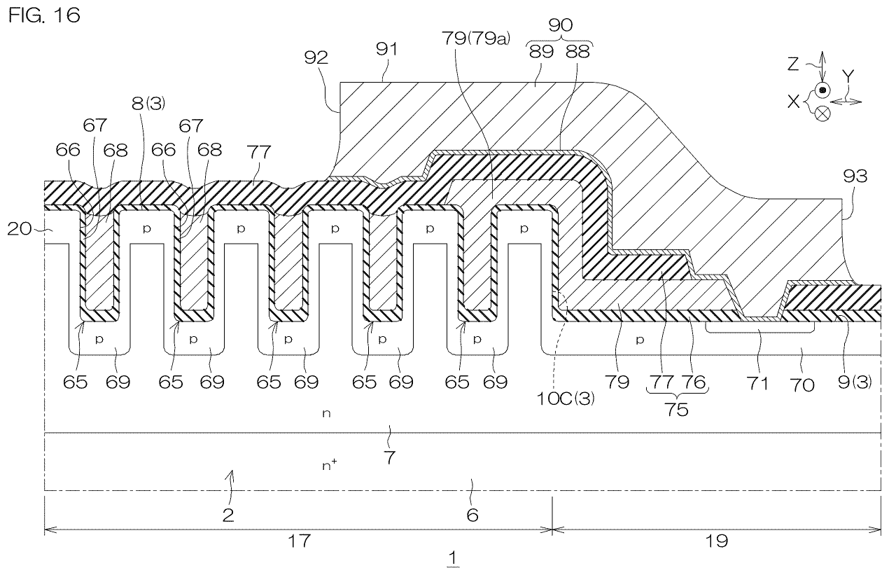

Hereinafter, the arrangement of the fifth end portion region 17 will be described. FIG. 15 is an enlarged view of a portion surrounded by an alternate long and short dashed line XV in FIG. 4. FIG. 16 is a sectional view taken along line XVI-XVI shown in FIG. 15. Since the layout of the sixth end portion region 18 is similar to the layout of the fifth end portion region 17, the description of the layout of the sixth end portion region 18 will be omitted. The layout of the sixth end portion region 18 is obtained by replacing the “fifth end portion region 17” with the “sixth end portion region 18,” replacing the “third end portion region 15” with the “fourth end portion region 16,” and replacing the “first connecting surface portion 10A” with the “second connecting surface portion 10B” in the description of the fifth end portion region 17.

The semiconductor device 1 includes a plurality of fourth source structures 65 of the trench type formed in the first surface portion 8 (the first principal surface 3) in the fifth end portion region 17. The source potential is applied to the plurality of fourth source structures 65.

The plurality of fourth source structures 65 are formed in a region to the first connecting surface portion 10A side with respect to the active region 12 (the third end portion region 15). In plan view, the plurality of fourth source structures 65 each extend in a band shape in the first direction X and are aligned at intervals in the second direction Y. In plan view, the plurality of fourth source structures 65 are aligned in a stripe shape extending in the first direction X. The plurality of fourth source structures 65 are adjacent to each other without any other trench structure interposed therebetween.

One fourth source structure 65 includes a sixth trench 66, a sixth insulating film 67, and a sixth embedded electrode 68. The sixth trench 66 is formed in the first surface portion 8 and demarcates wall surfaces (the side walls and the bottom wall) of the fourth source structure 65. Side walls of the sixth trench 66 are connected to either or both (in this preferred embodiment, both) of the third connecting surface portion 10C and the fourth connecting surface portion 10D. A bottom wall of the sixth trench 66 is connected to the second surface portion 9. The sixth insulating film 67 covers wall surfaces of the sixth trench 66. The sixth embedded electrode 68 is embedded in the sixth trench 66 with the sixth insulating film 67 interposed therebetween. The sixth embedded electrode 68 may contain either or both of a conductive polysilicon of the p-type and a conductive polysilicon of the n-type.

As shown in FIG. 16, the semiconductor device 1 includes a plurality of p-type sixth well regions 69 formed in a region along the plurality of fourth source structures 65 in the surface layer portion of the first surface portion 8 (first principal surface 3) of the fifth end portion region 17. The sixth well regions 69 have a p-type impurity concentration higher than the p-type impurity concentration of the body region 20.

The plurality of sixth well regions 69 are respectively formed in a one-to-one correspondence with respect to the plurality of fourth source structures 65. The plurality of sixth well regions 69 are respectively formed in the regions along the corresponding fourth source structures 65 at intervals from each other. The plurality of sixth well regions 69 are formed along the side walls and the bottom walls of the corresponding fourth source structures 65 and are each electrically connected to the body region 20 in the surface layer portion of the first surface portion 8. The plurality of sixth well regions 69 form pn junction portions with the second semiconductor region 7.

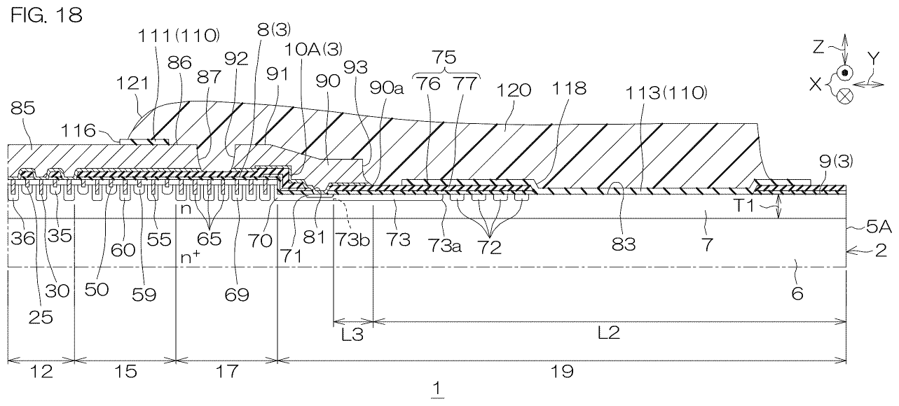

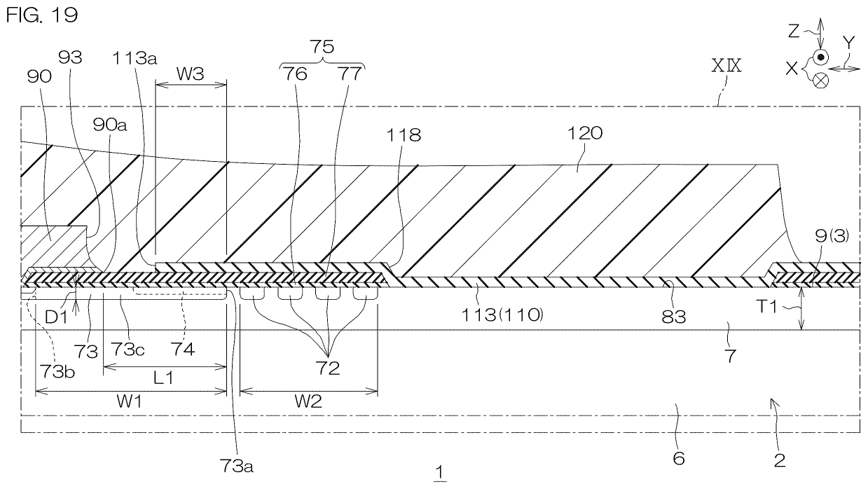

Hereinafter, the arrangement at the outer peripheral region 19 side shall be described. FIG. 17 is a sectional view showing a sectional structure taken along line XVII-XVII shown in FIG. 1 together with the outer peripheral structure according to a first configuration example. FIG. 18 is a sectional view taken along line XVIII-XVIII shown in FIG. 1. FIG. 19 is an enlarged view of a portion surrounded by an alternate long and short dashed line XIX in FIG. 17.

The semiconductor device 1 includes an outer well region 70 of the p-type formed in a surface layer portion of the second surface portion 9 in the outer peripheral region 19. The source potential is applied to the outer well region 70.

The p-type impurity concentration of the outer well region 70 is higher than the n-type impurity concentration of the second semiconductor region 7. The p-type impurity concentration of the outer well region 70 is lower than the p-type impurity concentration of the contact region 37. The p-type impurity concentration of the outer well region 70 is higher than the p-type impurity concentration of the body region 20. The p-type impurity concentration of the outer well region 70 may be substantially equal to the p-type impurity concentration of the first well region 35 (the p-type impurity concentration of the second well region 36). The p-type impurity concentration of the outer well region 70 may be less than the p-type impurity concentration of the body region 20.

The outer well region 70 is formed at an interval to the first surface portion 8 side from the peripheral edge of the second surface portion 9 in plan view. The outer well region 70 extends in a band shape along the first surface portion 8 in plan view. In this preferred embodiment, the outer well region 70 is formed in a polygonal annular shape (more specifically, a quadrangle annular shape) having four sides parallel to peripheral edges of the chip 2 and surrounds the first surface portion 8 in plan view. The outer well region 70 may have an edge portion connecting, in an arcuate shape (preferably, a quarter arcuate shape), a portion extending in the first direction X and a portion extending in the second direction Y.

The outer well region 70 extends from the surface layer portion of the second surface portion 9 to surface layer portions of the first to fourth connecting surface portions 10A to 10D and has a portion extending in the vertical direction Z along the first to fourth connecting surface portions 10A to 10D. The outer well region 70 is electrically connected to the body region 20 in a surface layer portion of the first surface portion 8. At the third connecting surface portion 10C (the fourth connecting surface portion 10D), the outer well region 70 is connected to the second well regions 36, the third well regions 44, the fourth well regions 59, the fifth well regions 60, and the sixth well regions 69.

The outer well region 70 is formed at an interval to the first principal surface 3 side from the bottom portion of the second semiconductor region 7. The outer well region 70 faces the first semiconductor region 6 in the depth direction of the chip 2 with a part of the second semiconductor region 7 interposed therebetween. The bottom portion of the outer well region 70 is positioned at the bottom portion side of the second semiconductor region 7 with respect to the depth positions of the bottom walls of the gate structures 25. The bottom portion of the outer well region 70 is formed at a depth position substantially equal to the bottom portion of the first well region 35 and the bottom portion of the second well region 36.

The outer well region 70 forms a pn junction portion with the second semiconductor region 7. The outer well region 70 spreads a depletion layer toward the second semiconductor region 7 when a reverse bias voltage is applied. The depletion layer of the outer well region 70 spreads in the horizontal directions and the thickness direction and becomes integral with a depletion layer spreading from the active region 12 side. The outer well region 70 expands the depletion layer, spreading from the active region 12, toward the peripheral edge sides of the second surface portion 9 and relaxes an electric field strength (a concentration of electric field) at the peripheral edges of the first surface portion 8 (at the first to fourth connecting surface portions 10A to 10D).

Referring to FIGS. 17 to 19, the semiconductor device 1 includes an outer contact region 71 of the p-type formed in the surface layer portion of the second surface portion 9 in the outer peripheral region 19. The p-type impurity concentration of the outer contact region 71 is higher than the p-type impurity concentration of the body region 20. The p-type impurity concentration of the outer contact region 71 is higher than the p-type impurity concentration of the outer well region 70. The p-type impurity concentration of the outer contact region 71 is substantially equal to the p-type impurity concentration of the contact region 37.

In the surface layer portion of the second surface portion 9, the outer contact region 71 is formed at intervals from the peripheral edges of the first surface portion 8 (the first to fourth connecting surface portions 10A to 10D) and the peripheral edges of the second surface portion 9 (the first to fourth side surfaces 5A to 5D) in plan view. Specifically, the outer contact region 71 is formed in a surface layer portion of the outer well region 70. The outer contact region 71 is formed at an interval to the second surface portion 9 side from the bottom portion of the outer well region 70 and faces the second semiconductor region 7 with a portion of the outer well region 70 interposed therebetween in the depth direction of the chip 2.

The outer contact region 71 extends in a band shape along the first surface portion 8 in plan view. In this preferred embodiment, the outer contact region 71 is formed in a polygonal annular shape (in this preferred embodiment, a quadrangle annular shape) having four sides parallel to the peripheral edges of the chip 2 and surrounds the first surface portion 8 in plan view. The outer contact region 71 may have an edge portion connecting, in an arcuate shape (preferably, a quarter arcuate shape), a portion extending in the first direction X and a portion extending in the second direction Y.

The outer contact region 71 is formed in a surface layer portion of the outer well region 70. The bottom portion of the outer contact region 71 is positioned at the second surface portion 9 (the first principal surface 3) side with respect to the bottom portion of the outer well region 70.

Referring to FIGS. 17 to 19, the semiconductor device 1 includes a terminal region 73 of the p-type formed in the surface layer portion of the second surface portion 9 in the outer peripheral region 19. The terminal region 73 may be referred to as a “terminal well region,” a “JTE region (Junction Termination Extension region),” etc. A source potential is applied to the terminal region 73.

In the surface layer portion of the second surface portion 9, the terminal region 73 is formed at intervals from the peripheral edges of the first surface portion 8 (first to fourth connecting surface portions 10A to 10D) and the peripheral edges of the second surface portion 9 (first to fourth side surfaces 5A to 5D) in plan view. The terminal region 73 extends in a band shape along the peripheral edges of the first principal surface 3 in plan view.

In this preferred embodiment, the terminal region 73 is formed in a polygonal annular shape (a quadrangle annular shape in this preferred embodiment) having four sides parallel to the peripheral edges of the chip 2 in plan view, and surrounds the inner portion (the active region 12) of the first principal surface 3 and the outer well region 70. The terminal region 73 may have an edge portion connecting, in an arcuate shape (preferably, a quarter arcuate shape), a portion extending in the first direction X and a portion extending in the second direction Y.

As a matter of course, the terminal region 73 may have a plurality of portions aligned at intervals along the inner portion (the active region 12) of the first principal surface 3 and the outer well region 70 such as to surround the inner portion (the active region 12) of the first principal surface 3 and the outer well region 70. In this case, the plurality of portions may extend in a band shape along the inner portion (the active region 12) of the first principal surface 3 and the outer well region 70.

Referring to FIGS. 17 to 19, the terminal region 73 has an inner edge 73b at the inner side of the first principal surface 3 and an outer edge 73a at the peripheral edge side of the first principal surface 3. The inner edge 73b of the terminal region 73 is connected to the outer edge of the outer well region 70. The inner edge 73b of the terminal region 73 is connected to the outer edge of the outer contact region 71. The terminal region 73 is electrically connected to the outer well region 70. The terminal region 73 is electrically connected to the outer contact region 71. Although not shown, the inner edge 73b of the terminal region 73 may be formed at intervals to the peripheral edges of the first principal surface 3 from the outer edges of the outer contact region 71.

Referring to FIG. 19, a width of the terminal region 73 (a distance between the outer edge 73a and the inner edge 73b in the first direction X or the second direction Y (a third width)) W1 may be not less than 0 μm and not more than 30 μm. The width W1 of the terminal region 73 may have a value belonging to at least one range among not less than 0 μm and not more than 5 μm, not less than 5 μm and not more than 10 μm, not less than 10 μm and not more than 15 μm, not less than 15 μm and not more than 20 μm, not less than 20 μm and not more than 25 μm, and not less than 25 μm and not more than 30 μm. In the example in FIG. 19, the width W1 of the terminal region 73 is preferably not less than 10 μm and not more than 20.

The width ratio of the width W1 of the terminal region 73 to the width of the outer well region 70 (the distance between the outer edge and the inner edge of the outer well region 70 in the first direction X or the second direction Y) may be not less than 0.5 and not more than 5. The width ratio may have a value belonging to at least one range among not less than 0.5 and not more than 0.75, not less than 0.75 and not more than 1, not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, not less than 2.75 and not more than 3, not less than 3 and not more than 3.25, not less than 3.25 and not more than 3.5, not less than 3.5 and not more than 3.75, not less than 3.75 and not more than 4, not less than 4 and not more than 4.25, not less than 4.25 and not more than 4.5, not less than 4.5 and not more than 4.75, and not less than 4.75 and not more than 5. The width W1 of the terminal region 73 is preferably greater than the width of the outer well region 70. As a matter of course, the width W1 of the terminal region 73 may be not more than the width of the outer well region 70.

The terminal region 73 is formed in the second surface portion 9 (the first principal surface 3). The terminal region 73 has a bottom portion positioned at the bottom portion side of the second semiconductor region 7. The bottom portion of the terminal region 73 forms a pn-junction portion with the second semiconductor region 7.

In the examples in FIGS. 17 to 19, the bottom portion of the terminal region 73 has a flat bottom surface continuing from the first principal surface 3 side toward the peripheral edge side of the second surface portion 9. A depth D1 of the terminal region 73 is substantially constant. As a matter of course, the depth D1 (a first depth) of the terminal region 73 may gradually increase toward the peripheral edge side of the second surface portion 9. The depth of the terminal region 73 may gradually decrease toward the peripheral edge side of the second surface portion 9.

In this preferred embodiment, the bottom portion of the terminal region 73 is positioned at the bottom portion side of the second semiconductor region 7 with respect to the depth position of the bottom portion of the body region 20. The bottom portion of the terminal region 73 may be positioned at the first principal surface 3 side with respect to the depth position of the bottom portion of the body region 20.

The depth position of the bottom portion of the terminal region 73 may be equal to the depth position of the bottom portion of the second well region 36. The depth D1 (the first depth) of the terminal region 73 may be equal to a depth DW2 (a second depth, see FIGS. 6 and 7) of the second well region 36 (D1=DW2). In this case, the depth position of the bottom portion of the terminal region 73 may be placed at the bottom portion side of the second semiconductor region 7 with respect to the depth position of the bottom portion of the first well region 35. The depth D1 (the first depth) of the terminal region 73 may be greater than a depth DW1 (see FIGS. 6 and 7) of the first well region 35 (D1>DW1). As a matter of course, the depth D1 (the first depth) of the terminal region 73 may be positioned at the bottom portion side of the second semiconductor region 7 with respect to the depth position of the bottom portion of the second well region 36 (D1>DW2). The depth D1 (the first depth) of the terminal region 73 may be positioned at the first principal surface 3 side with respect to the depth position of the bottom portion of the second well region 36 (D1<DW2).

The bottom portion of the terminal region 73 is positioned at a depth position substantially equal to the bottom portion of the outer well region 70. The bottom portion of the terminal region 73 is flush with the bottom portion of the outer well region 70. As a matter of course, the bottom portion of the terminal region 73 may be positioned at the bottom portion side of the second semiconductor region 7 with respect to the depth position of the bottom portion of the outer well region 70, or may be positioned at the first principal surface 3 side with respect to the depth position of the bottom portion of the outer well region 70.

The depth (the first depth) D1 of the terminal region 73 may be more than 0 μm and not more than 4 μm. The depth D1 of the terminal region 73 may have a value belonging to any one range among more than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.5 μm and not more than 2.75 μm, not less than 2.75 μm and not more than 3 μm, not less than 3 μm and not more than 3.25 μm, not less than 3.25 μm and not more than 3.5 μm, not less than 3.5 μm and not more than 3.75 μm, and not less than 3.75 μm and not more than 4 μm. The depth D1 of the terminal region 73 is preferably not less than 0.5 μm and not more than 3 μm. In this preferred embodiment, since the terminal region 73 is formed in the first principal surface 3, the depth D1 of the terminal region 73 matches the thickness of the terminal region 73.

The p-type impurity concentration of the terminal region 73 is not less than 1.0×1018 cm−3 and not more than 5.0×1020 cm−3 . The p-type impurity concentration of the terminal region 73 is higher than the n-type impurity concentration of the second semiconductor region 7. The p-type impurity concentration of the terminal region 73 is lower than the p-type impurity concentration of the contact region 37. The p-type impurity concentration of the terminal region 73 is lower than the p-type impurity concentration of the outer contact region 71. The p-type impurity concentration of the terminal region 73 may be higher than the p-type impurity concentration of the body region 20, or may be lower than the p-type impurity concentration of the body region 20. The p-type impurity concentration of the terminal region 73 may be equal to the p-type impurity concentration of the second well region 36 (first well region 35), may be higher than the p-type impurity concentration of the second well region 36 (first well region 35), or may be lower than the p-type impurity concentration of the second well region 36 (first well region 35). The p-type impurity concentration of the terminal region 73 may be equal to the p-type impurity concentration of the outer well region 70, may be higher than the p-type impurity concentration of the outer well region 70, or may be lower than the p-type impurity concentration of the outer well region 70.

The terminal region 73 forms a pn junction portion with the second semiconductor region 7. The terminal region 73 spreads a depletion layer toward the second semiconductor region 7 when a reverse bias voltage is applied. The depletion layer of the terminal region 73 spreads in the horizontal directions and the thickness direction, and the depletion layer of the outer well region 70 becomes integral with the depletion layer of the terminal region 73. The terminal region 73 expands the depletion layer, spreading from the active region 12, toward the peripheral edge sides of the second surface portion 9 and relaxes an electric field strength (a concentration of electric field) at the peripheral edges of the first surface portion 8 (at the first to fourth connecting surface portions 10A to 10D).

As described above, the terminal region 73 is electrically connected to the body region 20 and the outer contact region 71 via the outer well region 70. The outer contact region 71 is electrically connected to a source electrode 85 and a source wiring 90 that will be described later. The terminal region 73 is electrically connected to the source electrode 85 and the source wiring 90.

Referring to FIGS. 17 to 19, the semiconductor device 1 includes at least one field region 72 of the p-type formed in the surface layer portion of the second surface portion 9 in the outer peripheral region 19. The field region 72 may be formed in an electrically floating state or may be fixed at the source potential. A plurality of field regions 72 relax an electric field inside the chip 2 in the outer peripheral region 19.

The number of field regions 72 is feely selected. The number of field regions 72 may be not less than 1 and not more than 20. The number of field regions 72 may have a value belonging to at least one range among not less than 1 and not more than 5, not less than 5 and not more than 10, not less than 10 and not more than 15, and not less than 15 and not more than 20. The number of field regions 72 is typically not less than 1 and not more than 8. In this preferred embodiment, the semiconductor device 1 includes a plurality of (for example, four) field regions 72.

The plurality of field regions 72 are formed in the surface layer portion of the second surface portion 9 at intervals from the peripheral edges of the first surface portion 8 (from the first to fourth connecting surface portions 10A to 10D) and from the peripheral edges of the second surface portion 9 (from the first to fourth side surfaces 5A to 5D) in plan view. Specifically, the plurality of field regions 72 are formed at intervals to the peripheral edge side of the second surface portion 9 from the terminal region 73 in a region between the peripheral edges of the second surface portion 9 and the terminal region 73.

The plurality of field regions 72 are formed at intervals to the second surface portion 9 side from the bottom portion of the second semiconductor region 7. The plurality of field regions 72 are formed in the second surface portion 9. The plurality of field regions 72 face the first semiconductor region 6 in the depth direction of the chip 2 with a portion of the second semiconductor region 7 interposed therebetween. The plurality of field regions 72 each extend in a band shape along the first surface portion 8 in plan view.

In this preferred embodiment, the plurality of field regions 72 are each formed in a polygonal annular shape (in this preferred embodiment, a quadrangle annular shape) having four sides parallel to peripheral edges of the chip 2 and surround the first surface portion 8 in plan view. The plurality of field regions 72 may each have an edge portion connecting, in an arcuate shape (preferably, a quarter arcuate shape), a portion extending in the first direction X and a portion extending in the second direction Y.

Each of the plurality of field regions 72 forms a pn junction portion with the second semiconductor region 7. The plurality of field regions 72 each spread a depletion layer toward the second semiconductor region 7 when the reverse bias voltage is applied. The depletion layers of the plurality of field regions 72 each spread in the horizontal direction and the thickness direction, and become integral with the depletion layer of the outer well region 70 and the depletion layer of the terminal region 73. The plurality of field regions 72 expand the depletion layer, spreading from the active region 12, toward the peripheral edge sides of the second surface portion 9 and relax the electric field strength (the concentration of electric field) at the peripheral edges of the first surface portion 8 (at the first to fourth connecting surface portions 10A to 10D).

The p-type impurity concentrations of the plurality of field regions 72 may be substantially equal to the p-type impurity concentration of the terminal region 73. The p-type impurity concentration of the plurality of field regions 72 may be higher than the p-type impurity concentration of the terminal region 73, or may be lower than the p-type impurity concentration of the terminal region 73.

The p-type impurity concentrations of the plurality of field regions 72 may be substantially equal to the p-type impurity concentration of the outer well region 70. The p-type impurity concentrations of the plurality of field regions 72 may be higher than the p-type impurity concentration of the outer well region 70 or may be less than the p-type impurity concentration of the outer well region 70.

The p-type impurity concentrations of the plurality of field regions 72 may be substantially fixed or may be non-uniform. The p-type impurity concentrations of the plurality of field regions 72 may increase gradually toward the peripheral edge sides of the second surface portion 9. The p-type impurity concentrations of the plurality of field regions 72 may decrease gradually toward the peripheral edge sides of the second surface portion 9.

The widths of the plurality of field regions 72 may be substantially fixed or may be non-uniform. The widths of the plurality of field regions 72 may increase gradually toward the peripheral edge sides of the second surface portion 9. The widths of the plurality of field regions 72 may decrease gradually toward the peripheral edge sides of the second surface portion 9. The intervals of the plurality of field regions 72 may be substantially fixed or may be non-uniform. The intervals of the plurality of field regions 72 may increase gradually toward the peripheral edge sides of the second surface portion 9. The intervals of the plurality of field regions 72 may decrease gradually toward the peripheral edge sides of the second surface portion 9.

As shown in FIG. 19, the total width of the plurality of field regions 72 (a width between the inner edge of the innermost field region 72 and the outer edge of the outermost field region 72 (a second width)) W2 may be not less than 5 μm and not more than 30 μm. The width W2 may have a value belonging to at least one range among not less than 5 μm and not more than 10 μm, not less than 10 μm and not more than 15 μm, not less than 15 μm and not more than 20 μm, not less than 20 μm and not more than 25 μm, and not less than 25 μm and not more than 30 μm. The width W2 is 15 μm in the example in FIG. 19. The total width W2 of the plurality of field regions 72 may be smaller than the width W1 of the terminal region 73. As a matter of course, the width W2 may be equal to the width W1 or may be greater than the width W1.

The bottom portions of the plurality of field regions 72 are positioned at approximately equal depth positions to the bottom portions of the terminal regions 73. The bottom portions of the plurality of field regions 72 are flush with the bottom portion of the terminal region 73. As a matter of course, the bottom portions of the plurality of field regions 72 may be positioned at the bottom portion side of the second semiconductor region 7 with respect to the depth position of the bottom portion of the terminal region 73, or may be positioned at the first principal surface 3 side with respect to the depth position of the bottom portion of the terminal region 73.

The depths of the plurality of field regions 72 may be substantially fixed or may be non-uniform. The depths of the plurality of field regions 72 may increase gradually toward the peripheral edge sides of the second surface portion 9. The depths of the plurality of field regions 72 may decrease gradually toward the peripheral edge sides of the second surface portion 9.

Referring to FIGS. 11, 12, and 16 to 18, the semiconductor device 1 includes an insulating first inorganic film (a first insulating film) 75 that selectively covers the first principal surface 3. The first inorganic film 75 may be referred to as a “first inorganic insulating film” etc. The first inorganic film 75 selectively covers the first surface portion 8, the second surface portion 9, and the first to fourth connecting surface portions 10A to 10D. In this preferred embodiment, the first inorganic film 75 is continuous with the peripheral edges of the second surface portion 9 (continuous with the peripheral edges of the first to fourth side surfaces 5A to 5D). The first inorganic film 75 is formed to be flush with the second surface portion 9. The first inorganic film 75 has a laminated structure that includes a lower inorganic film 76 and an upper inorganic film 77.

The lower inorganic film 76 selectively covers the first surface portion 8, the second surface portion 9, and the first to fourth connecting surface portions 10A to 10D. The lower inorganic film 76 may be referred to as a “base insulating film,” a “principal surface insulating film,” etc. In the first surface portion 8, the lower inorganic film 76 is connected to the first insulating films 27, the second insulating films 32, the third insulating films 42, the fourth insulating films 52, the fifth insulating films 57, and the sixth insulating films 67 and exposes the first embedded electrodes 28, the second embedded electrodes 33, the third embedded electrodes 43, the fourth embedded electrodes 53, the fifth embedded electrodes 58, and the sixth embedded electrodes 68.

In the second surface portion 9, the lower inorganic film 76 covers the outer well region 70, the outer contact region 71, the terminal region 73, and the plurality of field regions 72. At the first to fourth connecting surface portions 10A to 10D, the lower inorganic film 76 is connected to the second insulating films 32, the third insulating films 42, the fourth insulating films 52, the fifth insulating films 57, and the sixth insulating films 67 and exposes the second embedded electrodes 33, the third embedded electrodes 43, the fourth embedded electrodes 53, the fifth embedded electrodes 58, and the sixth embedded electrodes 68.

At the first to fourth connecting surface portions 10A to 10D, the lower inorganic film 76 covers the body region 20, the second well regions 36, the third well regions 44, the fourth well regions 59, the fifth well regions 60, the sixth well regions 69, the outer well region 70, and the terminal region 73.

The lower inorganic film 76 may include at least one among a silicon oxide film, a silicon nitride film, and a silicon oxynitride film. The lower inorganic film 76 preferably includes the same type of insulating material as the insulating material of the first insulating film 27, etc. In this preferred embodiment, the lower inorganic film 76 has a single layer structure constituted of a silicon oxide film. The lower inorganic film 76 particularly preferably includes a silicon oxide film that is constituted of the oxide of the chip 2.

The upper inorganic film 77 is laminated on the lower inorganic film 76 and selectively covers the first surface portion 8, the second surface portion 9, and the first to fourth connecting surface portions 10A to 10D with the lower inorganic film 76 interposed therebetween. The upper inorganic film 77 may be referred to as an “overlaying insulating film,” an “interlayer insulating film,” an “intermediate insulating film,” etc. The upper inorganic film 77 covers the plurality of gate structures 25, the plurality of first source structures 30, the plurality of second source structures 40, the plurality of dummy gate structures 50, the plurality of third source structures 55, and the plurality of fourth source structures 65 in the first surface portion 8.

The upper inorganic film 77 covers the outer well region 70, the outer contact region 71, the terminal region 73, and the plurality of field regions 72 with the lower inorganic film 76 interposed therebetween in the second surface portion 9. The upper inorganic film 77 covers the plurality of first source structures 30, the plurality of second source structures 40, the plurality of dummy gate structures 50, the plurality of third source structures 55, and the plurality of fourth source structures 65 at the first to fourth connecting surface portions 10A to 10D.

The upper inorganic film 77 may include at least one among a silicon oxide film, a silicon nitride film, and a silicon oxynitride film. The upper inorganic film 77 preferably includes a silicon oxide film. The upper inorganic film 77 preferably contains an insulating material with a property different from that of the insulating material of the lower inorganic film 76. For example, the upper inorganic film 77 preferably has a single layer structure or a laminated structure that includes at least one among a silicon oxide film that contains phosphorus (a PSG film), a silicon oxide film that contains phosphorus and boron (a BPSG film), a non-doped silicon oxide film (an NSG film), and a tetraethyl orthosilicate film (a TEOS film). For example, the upper inorganic film 77 may have a laminated structure that includes an NSG film laminated on the lower inorganic film 76 and a PSG film (or a BPSG film) laminated on the NSG film.

Referring to FIGS. 8 and 9, the semiconductor device 1 includes a plurality of gate connection electrodes 78 that selectively cover the plurality of gate structures 25 in the active region 12. The plurality of gate connection electrodes 78 contains either or both of a conductive polysilicon of the p-type and a conductive polysilicon of the n-type.

Referring to FIGS. 8, 10, etc., the semiconductor device 1 includes a side wall wiring 79 covering at least one of the first to fourth connecting surface portions 10A to 10D on the second surface portion 9. The side wall wiring 79 contains either or both of a conductive polysilicon of the p-type and a conductive polysilicon of the n-type. In this preferred embodiment, the side wall wiring 79 is formed integral to the second embedded electrodes 33, the third embedded electrodes 43, the fourth embedded electrodes 53, the fifth embedded electrodes 58, and the sixth embedded electrodes 68. In this preferred embodiment, the side wall wiring 79 is formed in a polygonal annular shape (specifically, a quadrangle annular shape) extending along the first to fourth connecting surface portions 10A to 10D and surrounds the first surface portion 8 in plan view.

The side wall wiring 79 is electrically connected to the plurality of first source structures 30, the plurality of second source structures 40, the plurality of dummy gate structures 50, the plurality of third source structures 55, and the plurality of fourth source structures 65 at the first to fourth connecting surface portions 10A to 10D. The side wall wiring 79 has an overlap portion 79a that overlaps onto an edge portion of the first surface portion 8 from at least one of the first to fourth connecting surface portions 10A to 10D. In this preferred embodiment, the overlap portion 79a overlaps onto the first surface portion 8 from all of the first to fourth connecting surface portions 10A to 10D and is formed in an annular shape (specifically, a quadrangle annular shape) surrounding an inner portion of the first surface portion 8.

Referring to FIGS. 6 and 7, the semiconductor device 1 has a plurality of source openings 80 formed in the first inorganic film 75 in the active region 12. The plurality of source openings 80 penetrate through the first inorganic film 75 and selectively expose the plurality of first source structures 30. Specifically, the plurality of source openings 80 are respectively formed in a one-to-one correspondence with respect to the plurality of source structures and each extend in a band shape along the corresponding first source structure 30.

Referring to FIGS. 2, 3, 17, and 18, the semiconductor device 1 has at least one (one in this preferred embodiment) outer opening 81 formed in the first inorganic film 75 in the outer peripheral region 19. The outer opening 81 penetrates through the first inorganic film 75 and exposes both the outer contact region 71 and the side wall wiring 79.

Specifically, the outer opening 81 penetrates through the upper inorganic film 77 and exposes the side wall wiring 79. Also, the outer opening 81 penetrates through both the lower inorganic film 76 and the upper inorganic film 77 and exposes the outer contact region 71. In plan view, the outer opening 81 extends in a band shape along the outer contact region 71 and the side wall wiring 79. In this preferred embodiment, the outer opening 81 is formed in a polygonal annular shape (specifically, a quadrangle annular shape) surrounding the first surface portion 8 in plan view.

The semiconductor device 1 has a plurality of gate openings 82 (see FIG. 9) formed in the first inorganic film 75 in the active region 12. The plurality of gate openings 82 penetrate through the first inorganic film 75 and selectively expose the plurality of gate structures 25. Specifically, the plurality of gate openings 82 are respectively formed in portions of the first inorganic film 75 that covers the plurality of gate connection electrodes 78 and respectively expose the plurality of gate connection electrodes 78. The plurality of gate openings 82 are formed in a one-to-one correspondence with respect to the plurality of gate connection electrodes 78 and each extend in a band shape in the first direction X in plan view.

As shown in FIGS. 2, 3, and 17 to 19, the semiconductor device 1 has at least one (one in this preferred embodiment) anchor opening 83 formed in the first inorganic film 75 in the outer peripheral region 19. The anchor opening 83 is selectively formed in a portion of the first inorganic film 75 that covers a peripheral edge portion of the second surface portion 9.

The anchor opening 83 is formed in a region between the first surface portion 8 and the second surface portion 9. Specifically, the anchor opening 83 is formed in a region between the peripheral edge of the second surface portion 9 and the terminal region 73. More specifically, the anchor opening 83 is formed in a region between the peripheral edge of the second surface portion 9 and the plurality of field regions 72 (the outermost field region 72).

The anchor opening 83 penetrates through the first inorganic film 75 and exposes the second surface portion 9. Specifically, the anchor opening 83 exposes the second semiconductor region 7. The anchor opening 83 may be formed at the same height position as the second surface portion 9. The anchor opening 83 may be dug in to the bottom portion side of the second semiconductor region 7 with respect to a height position of the second surface portion 9. That is, a bottom wall of the anchor opening 83 may be positioned at the bottom portion side of the second semiconductor region 7 with respect to the height position of the second surface portion 9.

The anchor opening 83 extends in a band shape along the first surface portion 8 in plan view. In this preferred embodiment, the anchor opening 83 is formed in a polygonal annular shape (specifically, a quadrangle annular shape) surrounding the first surface portion 8 in plan view. As a matter of course, the semiconductor device 1 may have a plurality of the anchor openings 83. In this case, the plurality of anchor openings 83 may be formed at intervals along the first surface portion 8 such as to surround the first surface portion 8.

The plurality of anchor openings 83 may be formed in a matrix or a staggered arrangement at intervals in the first direction X and the second direction Y such as to surround the first surface portion 8. As a matter of course, the plurality of anchor openings 83 may be formed in a stripe shape or in a lattice such as to surround the first surface portion 8. Also, the plurality of anchor openings 83 may be formed in a concentric shape such as to surround the first surface portion 8.

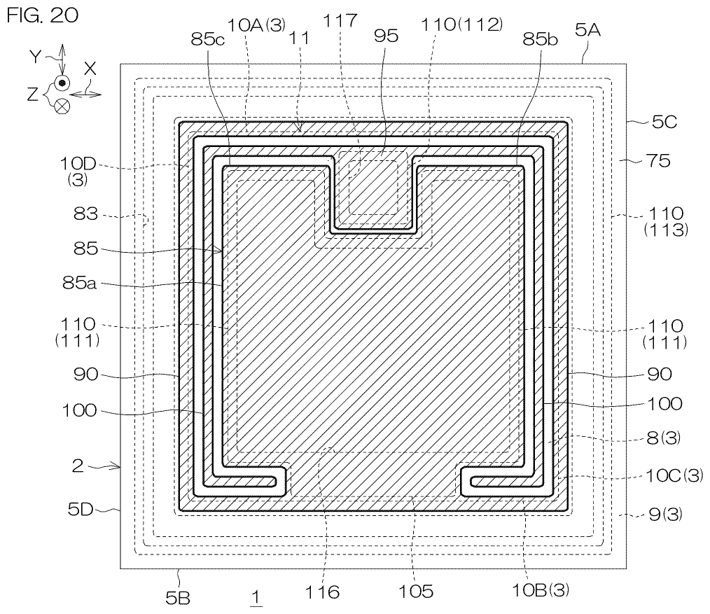

Hereinafter, the arrangement on the first principal surface 3 shall be described. FIG. 20 is a plan view showing a layout example of a principal electrode (a source electrode 85, a source wiring 90, a gate electrode 95, and a gate wiring 100) that is arranged on the first principal surface 3. Hereinafter, the arrangement of the principal electrode (the source electrode 85, the source wiring 90, the gate electrode 95, and the gate wiring 100) will be described. In FIG. 20, the principal electrode is hatched.

Referring to FIGS. 6, 7, 17, 20, etc., the semiconductor device 1 includes the source electrode (a peripheral edge source electrode portion) 85 arranged on the first inorganic film 75. The source electrode 85 is a terminal electrode to which the source potential is applied from an exterior. The source electrode 85 may be referred to as an “electrode,” a “first electrode,” a “first pad electrode,” a “first principal surface electrode,” a “first terminal electrode,” a “source pad electrode,” etc.

As shown in FIG. 20, the source electrode 85 is arranged on a covering portion of the first inorganic film 75 with respect to the first surface portion 8. In plan view, the source electrode 85 covers at least the entirety of the active region 12. The source electrode 85 covers the active region 12 at intervals from the first end portion region 13 and the second end portion region 14. The source electrode 85 covers the first surface portion 8 at intervals from both end portions of the plurality of gate structures 25. Specifically, the source electrode 85 is formed at intervals inward from the plurality of gate connection electrodes 78.

As shown in FIGS. 17 and 18, the source electrode 85 may cover one or both of the third end portion region 15 and the fifth end portion region 17. The source electrode 85 may face the plurality of dummy gate structures 50 and the plurality of third source structures 55 with the first inorganic film 75 interposed therebetween at the third end portion region 15 side. In addition, the source electrode 85 may face the plurality of fourth source structures 65 at the fifth end portion region 17 side. As a matter of course, the source electrode 85 may cover the active region 12 at an interval from either or both of the third end portion region 15 and the fifth end portion region 17.

As shown in FIGS. 6 and 7, the thickness of the source electrode 85 may be greater than the depth of the gate structure 25. The thickness of the source electrode 85 may be greater than the depth of the first source structure 30. The thickness of the source electrode 85 may be greater than the depth of the second surface portion 9. The thickness of the source electrode 85 may be greater than the thickness (a total thickness) of the first inorganic film 75.

As shown in FIG. 20, in this preferred embodiment, the source electrode 85 includes a first pad portion 85a, a second pad portion 85b, and a third pad portion 85c. The first pad portion 85a has a comparatively large planar area and forms a main body of the source electrode 85. In this preferred embodiment, the first pad portion 85a, in plan view, is formed in a polygonal shape (in this preferred embodiment, a quadrangle shape) having four sides parallel to the peripheral edges of the chip 2 and is shifted to the second side surface 5B (the second connecting surface portion 10B) side with respect to the first side surface 5A (the first connecting surface portion 10A).

The second pad portion 85b has a planar area less than a planar area of the first pad portion 85a and is led out in a band shape (quadrangle shape) toward the first connecting surface portion 10A from one end portion (an end portion at the third connecting surface portion 10C side) in the first direction X of the first pad portion 85a. The third pad portion 85c has a planar area less than the planar area of the first pad portion 85a, is led out in a band shape (quadrangle shape) toward the first connecting surface portion 10A from the other end portion (an end portion at the fourth connecting surface portion 10D side) in the first direction X of the first pad portion 85a, and faces the second pad portion 85b in the first direction X.

The planar area of the third pad portion 85c may be substantially equal to the planar area of the second pad portion 85b. As a matter of course, the planar area of the third pad portion 85c may be greater than the planar area of the second pad portion 85b or may be less than the planar area of the second pad portion 85b.

The ratio (area ratio) of the planar area of the source electrode 85 to the planar area of the first surface portion 8 is preferably not less than 0.5 and less than 1.0. The area ratio may have a value belonging to at least one range among not less than 0.5 and not more than 0.6, not less than 0.6 and not more than 0.7, not less than 0.7 and not more than 0.8, not less than 0.8 and not more than 0.9, and not less than 0.9 and less than 1.0.

The source electrode 85 enters into the plurality of source openings 80 from above the first inorganic film 75 and is electrically connected to the plurality of first source structures 30, the source region 21, and the plurality of contact regions 37 inside the plurality of source openings 80.

As shown in FIGS. 17 and 18, the source electrode 85 has a first electrode surface 86 and a first electrode side wall 87. The first electrode surface 86 extends along the first inorganic film 75. The first electrode surface 86 may have a plurality of depressions recessed toward the first surface portion 8 side at portions that cover the plurality of source openings 80. The first electrode side wall 87 is positioned on the first inorganic film 75. The first electrode side wall 87 is inclined obliquely downward from the first electrode surface 86 toward the first inorganic film 75. In this preferred embodiment, the first electrode side wall 87 is inclined obliquely downward in a curved shape from the first electrode surface 86 toward the first inorganic film 75.

As shown in FIGS. 6 and 7, in this preferred embodiment, the source electrode 85 has a laminated structure including a first lower electrode film 88 and a first upper electrode film 89 laminated in this order from the first inorganic film 75 side. The first lower electrode film 88 is laminated in a film shape as a base film (a barrier film) of the source electrode 85 on the first inorganic film 75 and forms a lower layer portion of the first electrode side wall 87 of the source electrode 85.

In this preferred embodiment, the first lower electrode film 88 has a laminated structure including a Ti film and a TiN film that are laminated in that order from the first inorganic film 75 side. The first lower electrode film 88 may instead have a single layer structure constituted of the Ti film or the TiN film. The first lower electrode film 88 has a thickness (a total thickness) less than the thickness (the total thickness) of the first inorganic film 75.

The first lower electrode film 88 entirely covers, in a film shape, a region of the first inorganic film 75 in which the plurality of source openings 80 are formed and enters into the plurality of source openings 80 from above the first inorganic film 75. The first lower electrode film 88 has a portion that covers an insulating principal surface of the first inorganic film 75 in a film shape, portions that cover wall surfaces of the plurality of source openings 80 in film shapes, and portions that cover the first surface portion 8 inside the plurality of source openings 80 in film shapes.

Specifically, the first lower electrode film 88 directly covers the insulating principal surface of the first inorganic film 75 and faces the plurality of gate structures 25 with the first inorganic film 75 interposed therebetween. The first lower electrode film 88 enters into the plurality of source openings 80 from above the insulating principal surface of the first inorganic film 75 and covers, in film shapes, the wall surfaces of the plurality of source openings 80. The first lower electrode film 88 covers, in film shapes, the first surface portion 8 inside the plurality of source openings 80. Inside the plurality of source openings 80, the first lower electrode film 88 is mechanically and electrically connected to the plurality of first source structures 30, the source region 21, and the plurality of contact regions 37.

As shown in FIGS. 6 and 7, the first upper electrode film 89 is laminated in a film shape on the first lower electrode film 88 as a main body portion of the source electrode 85, and forms an upper layer portion of the first electrode surface 86 and the first electrode side wall 87 of the source electrode 85. The first upper electrode film 89 includes a conductive material differing from the first lower electrode film 88. The first upper electrode film 89 may include at least one among an Al film, an Al alloy film, a Cu film, and a Cu alloy film. The Al alloy film may include at least one among an AlSi alloy film, an AlCu alloy film, and an AlSiCu alloy film.

The first upper electrode film 89 has a thickness greater than the thickness (the total thickness) of the first lower electrode film 88. The thickness of the first upper electrode film 89 is preferably greater than the thickness of the first inorganic film 75. The thickness of the first upper electrode film 89 is preferably greater than the depth of the gate structure 25. The thickness of the first upper electrode film 89 is preferably greater than the depth of the first source structure 30. The thickness of the first upper electrode film 89 is preferably greater than the depth of the second surface portion 9.

The first upper electrode film 89 entirely covers, in a film shape, the region of the first inorganic film 75 in which the plurality of source openings 80 are formed and refills the plurality of source openings 80. The first upper electrode film 89 has a portion that covers the insulating principal surface of the first inorganic film 75 with the first lower electrode film 88 interposed therebetween, portions that cover wall surfaces of the plurality of source openings 80 with the first lower electrode film 88 interposed therebetween, and portions that cover the first surface portion 8 with the first lower electrode film 88 interposed therebetween.

Specifically, the first upper electrode film 89 covers the insulating principal surface of the first inorganic film 75 with the first lower electrode film 88 interposed therebetween and faces the plurality of gate structures 25 with the first inorganic film 75 and the first lower electrode film 88 interposed therebetween. The first upper electrode film 89 enters into the plurality of source openings 80 from above the first inorganic film 75 and covers, in film shapes, the wall surfaces of the plurality of source openings 80 with the first lower electrode film 88 interposed therebetween.

The first upper electrode film 89 covers, in film shapes, the first surface portion 8 inside the plurality of source openings 80 with the first lower electrode film 88 interposed therebetween. Inside the plurality of source openings 80, the first upper electrode film 89 is electrically connected to the plurality of first source structures 30, the source region 21, and the plurality of contact regions 37 via the first lower electrode film 88.

Referring to FIGS. 2, 3, 6, 7, and 17 to 20, the semiconductor device 1 includes a source wiring (a peripheral edge source electrode portion) 90 arranged around the source electrode 85 on the first inorganic film 75. The same potential (the source potential) as the source potential applied to the source electrode 85 is applied to the source wiring 90. The source wiring 90 may be referred to as a “wiring,” a “first wiring,” a “finger electrode,” a “source finger,” etc.

As shown in FIGS. 17 and 18, the thickness of the source wiring 90 is greater than the depth of the gate structure 25. The thickness of the source wiring 90 is greater than the depth of the first source structure 30. The thickness of the source wiring 90 is greater than the depth of the second surface portion 9. The thickness of the source electrode 85 is preferably greater than the thickness (the total thickness) of the first inorganic film 75. The thickness of the source wiring 90 is preferably substantially equal to the thickness of the source electrode 85. As a matter of course, the thickness of the source wiring 90 may be greater than the thickness of the source electrode 85 or may be less than the thickness of the source electrode 85. The thickness of the source wiring 90 may be not less than 0.5 μm and not more than 5 μm.

As shown in FIGS. 18 and 20, the source wiring 90 has a wiring width smaller than the electrode width of the source electrode 85, and is selectively routed on the first inorganic film 75. The source wiring 90 extends in a band shape along the first electrode side wall 87 of the source electrode 85 at an interval from the first electrode side wall 87. The source wiring 90 preferably extends in a band shape at least along either of the third connecting surface portion 10C and the fourth connecting surface portion 10D. In this preferred embodiment, the source wiring 90 is formed in a polygonal annular shape (specifically, a quadrangle annular shape) extending along the first to fourth connecting surface portions 10A to 10D and surrounds the source electrode 85 in plan view.

In this preferred embodiment, the source wiring 90 is arranged on the first end portion region 13, the second end portion region 14, the third end portion region 15, the fourth end portion region 16, the fifth end portion region 17, and the sixth end portion region 18 in plan view, and surrounds the active region 12. The source wiring 90 may have an edge portion connecting, in an arcuate shape (preferably, a quarter arcuate shape), a portion extending in the first direction X and a portion extending in the second direction Y.

As shown in FIG. 20, the source wiring 90 is electrically connected to the source electrode 85 on the first surface portion 8. Specifically, the source wiring 90 has, in a portion extending along the second connecting surface portion 10B, a portion extending in a band shape in the second direction Y toward the source electrode 85 (the first pad portion 85a) and is connected to an end portion of the source electrode 85 (the first pad portion 85a). The source wiring 90 is formed as a lead-out wiring that is led out from the source electrode 85.

The source wiring 90 crosses at least one (in this preferred embodiment, all) of the first to fourth connecting surface portions 10A to 10D from the first surface portion 8 and is led out onto the second surface portion 9. In this preferred embodiment, the source wiring 90 is formed as an outermost peripheral wiring on the second surface portion 9. The source wiring 90 does not face another electrode in the horizontal directions along the insulating principal surface of the first inorganic film 75 in the outer peripheral region 19. In other words, the other electrodes are not interposed in a region between the peripheral edges of the second surface portion 9 and the source wiring 90.

As shown in FIGS. 2 and 3, the source wiring 90 covers the side wall wiring 79 with the first inorganic film 75 (the upper inorganic film 77) interposed therebetween on the first to fourth connecting surface portions 10A to 10D. The source wiring 90 enters into the outer opening 81 from above the first inorganic film 75 and is connected to both the outer contact region 71 and the side wall wiring 79 inside the outer opening 81.

The source wiring 90 is thereby electrically connected to the outer contact region 71 and the side wall wiring 79. The source wiring 90 transmits the source potential applied to the source electrode 85 to the first source structure 30, the second source structure 40, the dummy gate structure 50, the third source structure 55, and the fourth source structure 65 via the side wall wiring 79. In addition, the source wiring 90 transmits the source potential applied to the source electrode 85 to the outer well region 70 and the terminal region 73 via the outer contact region 71.

As shown in FIGS. 17 and 18, the source wiring 90 is arranged at intervals from the plurality of field regions 72 in the first surface portion 8 (inside the first principal surface 3) side, and faces a portion of the terminal region 73 and the entirety of the outer well region 70 with the first inorganic film 75 interposed therebetween. In this preferred embodiment, the source wiring 90 is arranged at an interval from the outer edge portion of the terminal region 73 toward the first surface portion 8 (inside the first principal surface 3) side, and covers the entirety of the outer well region 70 and the entirety of the outer contact region 71. The source wiring 90 covers a portion of the inner side (the source electrode 85 side) of the terminal region 73. The source wiring 90 exposes the plurality of field regions 72.

As shown in FIGS. 17 and 18, the source wiring 90 includes a first wiring surface 91, a first inner side wall 92 at the inner side (at the source electrode 85 side), and a first outer side wall 93 at the outer side (at the peripheral edge side of the chip 2). The portion of the first wiring surface 91 positioned on the first surface portion 8 is positioned at a height position substantially equal to the first electrode surface 86 of the source wiring 90. The portion of the first wiring surface 91 positioned on the second surface portion 9 is recessed further toward the second surface portion 9 side than the portion of the first wiring surface 91 positioned on the first surface portion 8. The portion of the first wiring surface 91 positioned on the second surface portion 9 is preferably positioned higher (further to the side of the portion of the first wiring surface 91 positioned on the first surface portion 8) than the height position of the first surface portion 8. As a matter of course, the portion of the first wiring surface 91 positioned on the second surface portion 9 may instead be positioned lower (further to the second surface portion 9 side) than the height position of the first surface portion 8.

As shown in FIGS. 17 and 18, the first inner side wall 92 is positioned on the covering portion of the first inorganic film 75 with respect to the first surface portion 8 at an interval from the first electrode side wall 87 of the source electrode 85. The first inner side wall 92 is inclined obliquely downward from the first wiring surface 91 toward the first inorganic film 75.

As shown in FIGS. 17 to 19, the first outer side wall 93 is positioned on the covering portion of the first inorganic film 75 with respect to the second surface portion 9. The first outer side wall 93 is inclined obliquely downward from the first wiring surface 91 toward the first inorganic film 75. In this preferred embodiment, the first outer side wall 93 is inclined obliquely downward in a curved shape from the first wiring surface 91 toward the first inorganic film 75. In this preferred embodiment, the lower end of the outer edge of the first outer side wall 93 is the outer edge (the first outer edge) 90a of the source wiring 90.

In this preferred embodiment, the first outer side wall 93 faces the outer well region 70 with the first inorganic film 75 interposed therebetween. The first outer side wall 93 faces the outer contact region 71 with the first inorganic film 75 interposed therebetween. The first outer side wall 93 does not face the plurality of field regions 72 in the vertical direction Z.

The first outer side wall 93 faces a part of the terminal region 73 with the first inorganic film 75 interposed therebetween. The first outer side wall 93 faces the inner edge 73b of the terminal region 73 with the first inorganic film 75 interposed therebetween. The first outer side wall 93 does not face the outer edge (the second outer edge) 73a of the terminal region 73 in the vertical direction Z.

As shown in FIG. 19, the outer edge 90a of the source wiring 90 is positioned inward (source electrode 85 side) from the outer edge 73a of the terminal region 73. In other words, the outer edge 73a of the terminal region 73 is positioned on the outer side (the peripheral edge side of the chip 2) from the outer edge 90a of the source wiring 90. A first distance L1 between the outer edge 73a of the terminal region 73 and the outer edge 90a of the source wiring 90 is not less than 10 μm.

The first distance L1 may be not less than 10 μm and not more than 50 μm. The first distance L1 may have a value belonging to at least one range among not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, and not less than 45 μm and not more than 50 μm. The first distance L1 is 16 μm in the example in FIG. 19.

The first distance L1 may be not less than the thickness T1 of the second semiconductor region 7. In a case where the second semiconductor region 7 includes an epitaxial layer, the first distance L1 may be not less than the thickness T1 of the epitaxial layer.

A second distance L2 (see FIGS. 17 and 18) between the outer edge 90a of the source wiring 90 and the peripheral edge of the first principal surface 3 (the first to fourth side surfaces 5A to 5D) may be not less than 20 μm and not more than 100 μm. The second distance L2 may have a value belonging to at least one range among not less than 20 μm and not more than 30 μm, not less than 30 μm and not more than 40 μm, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, and not less than 90 μm and not more than 100 μm. The second distance L2 is 50 μm in the examples in FIGS. 17 and 18.

A ratio (L1/L2) of the first distance L1 to the second distance L2 may be not less than 0.1 and not more than 0.6. The ratio (L1/L2) may have a value belonging to at least one range among not less than 0.1 and not more than 0.15, not less than 0.15 and not more than 0.2, not less than 0.2 and not more than 0.25, not less than 0.25 and not more than 0.3, not less than 0.3 and not more than 0.35, not less than 0.35 and not more than 0.4, not less than 0.4 and not more than 0.45, not less than 0.45 and not more than 0.5, not less than 0.5 and not more than 0.55, and not less than 0.55 and not more than 0.6. The ratio (L1/L2) is 0.16 in the examples in FIGS. 17 to 19.

The first distance L1 may be equal to the entire width (the second width) W2 of the plurality of field regions 72. As a matter of course, the first distance L1 may be greater than the entire width (the second width) W2 of the plurality of field regions 72. The first distance L1 may be less than the entire width (the second width) W2 of the plurality of field regions 72.

As shown in FIG. 19, the inner edge 73b of the terminal region 73 is positioned further toward the inner side (the first surface portion 8 side) of the first principal surface 3 than the outer edge (the first outer edge) 90a of the source wiring 90. A third distance L3 (see FIGS. 17 and 18) between the inner edge 73b of the terminal region 73 and the outer edge 90a of the source wiring 90 is not less than 5 μm.

The third distance L3 (see FIGS. 17 and 18) may be not less than 3 μm and not more than 20 μm. The third distance L3 may have a value belonging to at least one range among not less than 3 μm and not more than 5 μm, not less than 5 μm and not more than 10 μm, not less than 10 μm and not more than 15 μm, and not less than 15 μm and not more than 20 μm. The third distance L3 is about 10 μm in the examples in FIGS. 17 and 18. The first distance L1 is preferably greater than the third distance L3. As a matter of course, the first distance L1 may be not more than the third distance L3.

As shown in FIG. 10 etc., similarly to the source electrode 85, the source wiring 90 has a laminated structure including first lower electrode film 88 and first upper electrode film 89. The first lower electrode film 88 is laminated in a film shape as a base film (a barrier film) of the source wiring 90 on the first inorganic film 75 and forms a lower layer portion of the first outer side wall 93 of the source wiring 90.

The first lower electrode film 88 entirely covers, in a film shape, a region of the first inorganic film 75 in which the outer opening 81 is formed and enters into the outer opening 81 from above the first inorganic film 75. Inside the outer opening 81, the first lower electrode film 88 is mechanically and electrically connected to the outer contact region 71 and the side wall wiring 79.

As a main body portion of the source wiring 90, the first upper electrode film 89 is laminated in a film shape on the first lower electrode film 88 and forms the first wiring surface 91, an upper layer portion of the first inner side wall 92, and an upper layer portion of the first outer side wall 93 of the source wiring 90. The first upper electrode film 89 entirely covers, in a film shape, the region of the first inorganic film 75 in which the outer opening 81 is formed and refills the outer opening 81. Inside the outer opening 81, the first upper electrode film 89 is electrically connected to the outer contact region 71 and the side wall wiring 79 via the first lower electrode film 88.

In an interior of the chip 2, different electric field distributions are formed at the first surface portion 8 side (the active region 12 side) and the second surface portion 9 side (the outer peripheral region 19 side). For example, at the first surface portion 8 side, an electric field distribution that is substantially uniform along the first principal surface 3 is formed. On the other hand, at the second surface portion 9 side, a terminal portion of the electric field distribution formed at the first surface portion 8 side is formed and the electric field concentrates more readily than in the first surface portion 8.

The source electrode 85 is arranged on the active region 12 having a relatively low first electric field. On the other hand, the source wiring 90 is arranged on the outer peripheral region 19 having the second electric field higher than the first electric field.

Referring to FIGS. 2, 3, and 20, the semiconductor device 1 includes a gate electrode 95 arranged on the first inorganic film 75. The gate electrode 95 is a terminal electrode to which the gate potential is applied from the exterior.

As shown in FIG. 20, the gate electrode 95 is arranged on the first inorganic film 75 at an interval from the source electrode 85. The gate electrode 95 is arranged on a covering portion of the first inorganic film 75 that covers the first surface portion 8. The gate electrode 95, in plan view, is formed in a polygonal shape (in this preferred embodiment, a quadrangle shape) having four sides parallel to the peripheral edges of the chip 2. The gate electrode 95 has a planar area less than a planar area of the source electrode 85.

In this preferred embodiment, the gate electrode 95 does not have a direct electrical connection location to the plurality of gate structures 25 (see FIGS. 6, 7, etc.). As a matter of course, the gate electrode 95 may be electrically connected to the plurality of gate structures 25 via the plurality of gate openings 82 (see FIG. 9). As a matter of course, portions of the plurality of gate structures 25 positioned directly below the gate electrode 95 may be removed.

As shown in FIG. 2, the gate electrode 95 includes a second electrode surface 96 and a second electrode side wall 97. The second electrode surface 96 extends along the first inorganic film 75. The second electrode side wall 97 is positioned on the first inorganic film 75. The second electrode side wall 97 is inclined obliquely downward from the second electrode surface 96 toward the first inorganic film 75. In this preferred embodiment, the gate electrode 95 has a laminated structure that includes a second lower electrode film and a second upper electrode film that are laminated in that order from the first inorganic film 75 side.

Referring to FIGS. 9, 20, etc., the semiconductor device 1 includes a gate wiring 100 arranged around the source electrode 85 on the first inorganic film 75.

As shown in FIG. 20, the gate wiring 100 has a wiring width smaller than the electrode width of the gate electrode 95, and is selectively routed on the first inorganic film 75. The gate wiring 100 is arranged at intervals inward from the peripheral edges of the first surface portion 8. The gate wiring 100 is not positioned on the second surface portion 9.

The gate wiring 100 is electrically connected to the gate electrode 95 on the first surface portion 8. Specifically, the gate wiring 100 is connected to an end portion of the gate electrode 95 at the first connecting surface portion 10A side. The gate wiring 100 is formed as a lead-out wiring that is led out from the gate electrode 95. A connection portion of the gate electrode 95 and the gate wiring 100 may be regarded as a portion of the gate electrode 95. As shown in FIG. 9 etc., similarly to the gate electrode 95, the gate wiring 100 has a laminated structure including a second lower electrode film 98 and a second upper electrode film 99.

As shown in FIG. 9, the gate wiring 100 enters into the plurality of gate openings 82 from above the first inorganic film 75 and is electrically connected to the end portions (both end portions) of the plurality of gate structures 25 inside the plurality of gate openings 82. Specifically, the gate wiring 100 is mechanically and electrically connected to the plurality of gate connection electrodes 78 inside the plurality of gate openings 82 and is electrically connected to the plurality of gate structures 25 via the plurality of gate connection electrodes 78. The gate potential applied to the gate electrode 95 is thereby applied to the plurality of gate structures 25 via the gate wiring 100.

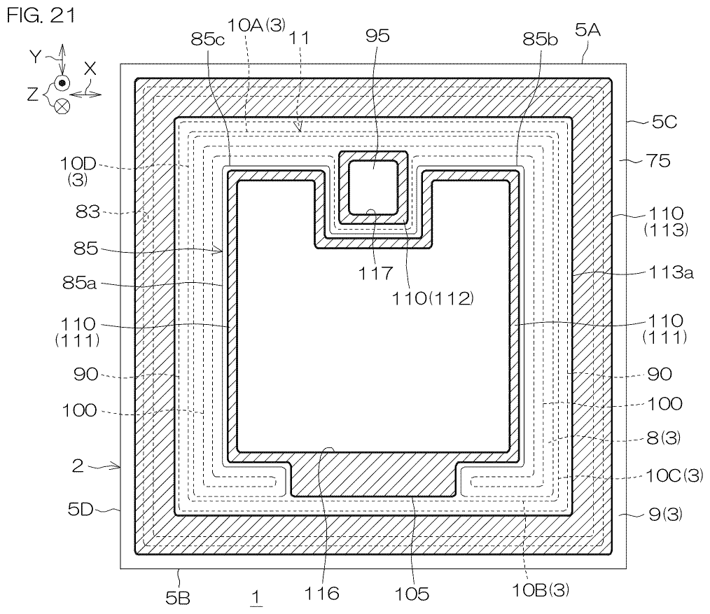

FIG. 21 is a plan view showing a layout example of a second inorganic film 110. In FIG. 21, the second inorganic film 110 is hatched. Hereinafter, the second inorganic film 110 will be described with reference to FIGS. 2, 3, 17 to 19, and 21.

The semiconductor device 1 includes the insulating second inorganic film (a second insulating film) 110 that selectively covers the first inorganic film 75. The second inorganic film 110 may be referred to as a “second inorganic insulating film,” an “upper insulating film,” a “passivation film,” etc. The second inorganic film 110 may include at least one among a silicon oxide film, a silicon nitride film, and a silicon oxynitride film.

The second inorganic film 110 preferably includes an insulating material differing from the insulating material of the first inorganic film 75. Specifically, the second inorganic film 110 preferably includes an insulating material differing from the insulating material of the upper inorganic film 77. In this preferred embodiment, the second inorganic film 110 has a single layer structure constituted of a silicon nitride film.

The second inorganic film 110 preferably has a thickness less than the thickness of the source electrode 85 (the gate electrode 95). The thickness of the second inorganic film 110 is preferably greater than thickness of the lower inorganic film 76. The thickness of the second inorganic film 110 is preferably greater than the thickness of the upper inorganic film 77. The thickness of the second inorganic film 110 is preferably greater than the thickness (the total thickness) of the first inorganic film 75. As a matter of course, the thickness of the second inorganic film 110 may be less than the thickness (the total thickness) of the first inorganic film 75. The thickness of the second inorganic film 110 may be less than the thickness of the upper inorganic film 77. The thickness of the second inorganic film 110 may be less than the thickness of the lower inorganic film 76.

The thickness of the second inorganic film 110 may be not less than 0.01 μm and not more than 5 μm. The thickness of the second inorganic film 110 may have a value belonging to at least one range among not less than 0.01 μm and not more than 0.1 μm, not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The thickness of the second inorganic film 110 is preferably not less than 0.1 μm and not more than 2 μm.

As shown in FIGS. 2, 3, and 21, the second inorganic film 110 selectively covers the source electrode 85, the source wiring 90, the gate electrode 95, and the gate wiring 100 on the first inorganic film 75. Specifically, the second inorganic film 110 includes a first inner covering portion 111, a second inner covering portion 112, and an outer covering portion 113.

In this preferred embodiment, the first inner covering portion 111 is formed in an annular shape surrounding an inner portion of the first electrode surface 86 in plan view. Specifically, the first inner covering portion 111 is formed in the polygonal annular shape (a U-shaped annular shape) conforming to a planar shape of the first electrode surface 86 in plan view.

The first inner covering portion 111 extends flatly on the first electrode surface 86. The first inner covering portion 111 covers a peripheral edge portion of the first electrode surface 86 (the source electrode 85) and exposes an inner side of the first electrode surface 86 (the source electrode 85). On the peripheral edge portion of the first electrode surface 86, the first inner covering portion 111 extends in a band shape along the first electrode side wall 87. The first inner covering portion 111 selectively covers the source electrode 85. Specifically, the first inner covering portion 111 covers the first electrode surface 86 of the source electrode 85 in a film shape such as to expose at least a portion of the first electrode side wall 87 of the source electrode 85. In this preferred embodiment, the first inner covering portion 111 exposes an entirety of the first electrode side wall 87.

As shown in FIG. 2, in this preferred embodiment, the first inner covering portion 111 has an extension portion 115 led out from above the source electrode 85 to above the connecting portion between the source electrode 85 and the source wiring 90. In this preferred embodiment, the extension portion 115 is formed wider than the other portions. As a matter of course, the extension portion 115 may have a width substantially equal to the other portions.

As shown in FIGS. 2, 3, 21, etc., the first inner covering portion 111 demarcates a first pad opening 116 that exposes the inner portion of the first electrode surface 86. The first pad opening 116 is demarcated in a polygonal shape having four sides parallel to the peripheral edges of the chip 2 in plan view. In this preferred embodiment, the first pad opening 116 is demarcated in a polygonal shape (a U-shape) conforming to the planar shape of the first electrode surface 86 in plan view.

As shown in FIGS. 2 and 21, the second inner covering portion 112 selectively covers the gate electrode 95. Specifically, the second inner covering portion 112 covers, in a film shape, the second electrode surface 96 (see FIG. 2) of the gate electrode 95 such as to expose at least a portion of the second electrode side wall 97 of the gate electrode 95. In this preferred embodiment, the second inner covering portion 112 exposes an entirety of the second electrode side wall 97 (see FIG. 2).

In this preferred embodiment, the second inner covering portion 112 is formed in an annular shape surrounding an inner portion of the second electrode surface 96 in plan view. The second inner covering portion 112 is formed in a polygonal annular shape (in this preferred embodiment, a quadrangle annular shape) having four sides parallel to the peripheral edges of the chip 2 in plan view. Specifically, the second inner covering portion 112 is formed in the polygonal annular shape (specifically, the quadrangle annular shape) conforming to a planar shape of the second electrode surface 96 in plan view.

The second inner covering portion 112 demarcates a second pad opening 117 that exposes the inner portion of the second electrode surface 96. The second pad opening 117 is demarcated in a polygonal shape (in this preferred embodiment, a quadrangle shape) having four sides parallel to the peripheral edges of the chip 2 in plan view.

As shown in FIGS. 17 to 19, FIG. 21, etc., the outer covering portion 113 selectively covers the first inorganic film 75 at intervals from the first inner covering portion 111 and the second inner covering portion 112. Specifically, the outer covering portion 113 is formed on a covering portion of the first inorganic film 75 that covers the second surface portion 9. The outer covering portion 113 extends in a band shape along the first surface portion 8 in plan view. The outer covering portion 113 is formed in an annular shape (in this preferred embodiment, a quadrangle annular shape) surrounding the first surface portion 8 in plan view.

The outer covering portion 113 extends in a film shape along the second surface portion 9 inside the anchor opening 83. In a covering portion that covers the anchor opening 83, the outer covering portion 113 demarcates an anchor recess 118 that is recessed toward the anchor opening 83. When a plurality of anchor openings 83 are formed in the first inorganic film 75, the outer covering portion 113 demarcates a plurality of anchor recesses 118. The anchor recess 118 has a planar shape substantially similar to a planar shape of the anchor opening 83. The anchor recess 118 extends in a band shape (in this preferred embodiment, an annular shape) along the anchor opening 83 in plan view.

In this preferred embodiment, the outer covering portion 113 is led out from the anchor opening 83 toward the peripheral edges of the second surface portion 9 (toward the first to fourth side surfaces 5A to 5D). The outer covering portion 113 is formed at intervals inward from the peripheral edges of the second surface portion 9 and exposes the first inorganic film 75 from the peripheral edge portions of the second surface portion 9.

As shown in FIGS. 19 and 21, the outer covering portion 113 has an inner edge 113a positioned between the first outer side wall 93 of the source wiring 90 and peripheral edges (the first to fourth side surfaces 5A to 5D) of the second surface portion 9. The inner edge 113a of the outer covering portion 113 is positioned between the anchor opening 83 and the first outer side wall 93 of the source wiring 90. The inner edge 113a of the outer covering portion 113 is positioned closer to the first surface portion 8 side (the first outer side wall 93 side) than the outer edge 73a of the terminal region 73. The inner edge 113a of the outer covering portion 113 extends along the second electrode side wall 97 at an interval from the second electrode side wall 97.

In this preferred embodiment, the outer covering portion 113 covers a portion of the outer side of the terminal region 73 (the peripheral edge side of the first principal surface 3) and the entireties of the plurality of field regions 72 with the first inorganic film 75 interposed therebetween at the second surface portion 9 side. The outer covering portion 113 exposes the outer well region 70 and the outer contact region 71.

As shown in FIG. 19, the distance between the inner edge 113a of the outer covering portion 113 and the outer edge 73a of the terminal region 73 (a width of a covered object portion 73c (the first width)) W3 may be not less than 10μm and not more than 50 μm. The width W3 may have a value belonging to at least one range among not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, and not less than 45 μm and not more than 50 μm. The width W3 may be not more than the entire width W2 of the plurality of field regions 72. The width W3 may be equal to the width W2, or may be less than the width W2 as in the first configuration example shown in FIG. 19. As a matter of course, the width W3 may be greater than the width W2.

Referring again to FIGS. 1 to 3, 17, and 18, the semiconductor device 1 includes an insulating organic film 120 that selectively covers the second inorganic film 110. The organic film 120 may be referred to as an “organic insulating film,” a “resin film,” etc. The organic film 120 preferably contains a transparent resin or a resin having translucency. The organic film 120 preferably contains a photosensitive resin. The photosensitive resin may be of a negative type or a positive type. The organic film 120 may include at least one among a polyimide film, a polyamide film, and a polybenzoxazole film.

The organic film 120 may have a thickness greater than the depth of the gate structure 25. The thickness of the organic film 120 may be greater than the thickness (the total thickness) of the first inorganic film 75. The thickness of the organic film 120 may be greater than the thickness of the source electrode 85 (the gate electrode 95). The thickness of the organic film 120 may be greater than the thickness of the second inorganic film 110. The thickness of the organic film 120 is preferably less than a thickness of the chip 2. The thickness of the organic film 120 may be greater than the thickness of the second semiconductor region 7 or may be less than the thickness of the second semiconductor region 7.

The organic film 120 crosses the first to fourth connecting surface portions 10A to 10D from above the first surface portion 8 and covers the second surface portion 9. The organic film 120 directly covers the first inner covering portion 111, the second inner covering portion 112, and the outer covering portion 113 of the second inorganic film 110.

The organic film 120 directly covers the first electrode side wall 87 of the source electrode 85 in a region between the first inner covering portion 111 and the outer covering portion 113. The organic film 120 directly covers the second electrode side wall 97 of the gate electrode 95 in a region between the second inner covering portion 112 and the outer covering portion 113. The organic film 120 directly covers both the first electrode side wall 87 of the source electrode 85 and the second electrode side wall 97 of the gate electrode 95 in a region between the first inner covering portion 111 and the second inner covering portion 112.

The organic film 120 covers the first inner covering portion 111 along its entire periphery and demarcates a first upper pad opening 121 that exposes an inner portion of the first electrode surface 86 (see FIG. 1 to FIG. 3). Specifically, the organic film 120 covers the first inner covering portion 111 at an interval to an outer edge (an outer wall) side from an inner edge (an inner wall) of the first inner covering portion 111 and exposes the inner edge of the first inner covering portion 111. A wall surface of the first upper pad opening 121 is positioned further to the first electrode side wall 87 side than a wall surface of the first pad opening 116 and faces the first electrode surface 86 with the first inner covering portion 111 interposed therebetween.

The organic film 120 covers the second inner covering portion 112 along its entire periphery and demarcates a second upper pad opening 122 that exposes an inner portion of the second electrode surface 96 (see FIG. 1 to FIG. 3). Specifically, the organic film 120 covers the second inner covering portion 112 at an interval to an outer edge (an outer wall) side from an inner edge (an inner wall) of the second inner covering portion 112 and exposes the inner edge of the second inner covering portion 112. A wall surface of the second upper pad opening 122 is positioned further to the second electrode side wall 97 side than a wall surface of the second pad opening 117 and faces the second electrode surface 96 with the second inner covering portion 112 interposed therebetween.

At the second surface portion 9 side, the organic film 120 covers the outer well region 70, the terminal region 73, and the plurality of field regions 72 with the first inorganic film 75 and the second inorganic film 110 interposed therebetween. At a peripheral edge portion of the second surface portion 9, the organic film 120 covers the anchor opening 83 with the second inorganic film 110 interposed therebetween. The organic film 120 is engaged with the anchor recess 118 of the second inorganic film 110 (the anchor opening 83 of the first inorganic film 75).

In this preferred embodiment, the organic film 120 is led out from the anchor opening 83 toward the peripheral edges of the second surface portion 9 (toward the first to fourth side surfaces 5A to 5D). The organic film 120 is formed at intervals inward from the peripheral edges of the second surface portion 9 and exposes the first inorganic film 75 from the peripheral edge portion of the second surface portion 9. In this preferred embodiment, the organic film 120 covers the outer covering portion 113 at an interval inward from an outer edge (an outer wall) of the outer covering portion 113 and exposes the outer edge of the outer covering portion 113.

Referring again to FIGS. 2 and 3, the semiconductor device 1 includes a drain electrode 125 covering the second principal surface 4. The drain electrode 125 is a terminal electrode to which the drain potential is applied from the exterior. The drain electrode 125 may be referred to as an “electrode,” a “third electrode,” a “third pad electrode,” a “third principal surface electrode,” a “third terminal electrode,” a “drain pad electrode,” etc.

The drain electrode 125 is electrically connected to the first semiconductor region 6. The drain electrode 125 may cover the entirety of the second principal surface 4 such as to be continuous with the peripheral edges of the second principal surface 4 (such as to be continuous with the first to fourth side surfaces 5A to 5D). The drain electrode 125 may cover the second principal surface 4 partially such as to expose a peripheral edge portion of the second principal surface 4.

A breakdown voltage applicable between the source electrode 85 and the drain electrode 125 (between the first principal surface 3 and the second principal surface 4) may be not less than 500 V and not more than 3000 V. The breakdown voltage may have a value belonging to at least one range among not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

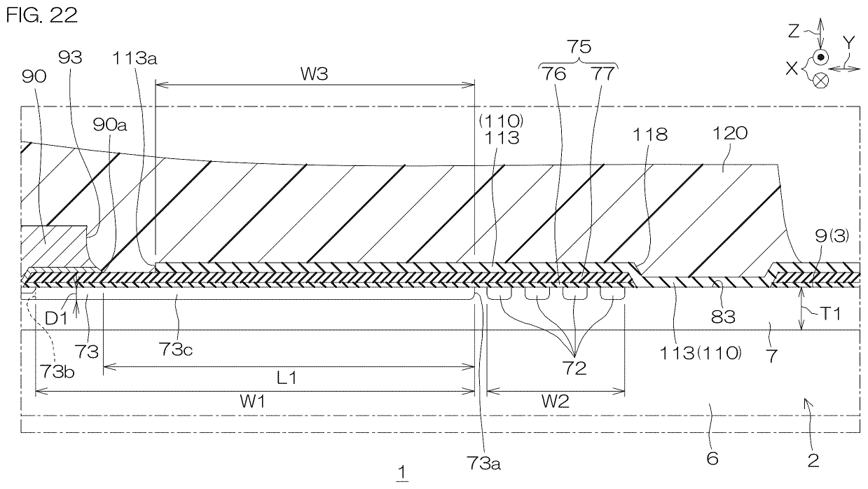

FIG. 22 is a sectional view showing the sectional structure of the semiconductor device 1 together with the outer peripheral structure according to the second configuration example, and is a view corresponding to FIG. 19.

In the second configuration example, the first distance L1 between the outer edge 90a of the source wiring 90 and the outer edge 73a of the terminal region 73 is greater than that in the first configuration example shown in FIGS. 17 to 19. In the example in FIG. 22, the first distance L1 is not less than 20 μm (for example, 30 μm). In the second configuration example, the first distance L1 is greater than the entire width (a second width) W2 of the plurality of field regions 72.

In other words, the width W3 of the covered object portion 73c (the distance between the inner edge of the outer covering portion 113 and the terminal region 73) is greater than the entire width W2 of the plurality of field regions 72. In other words, in the second configuration example, the first distance L1 is greater than the width W2. In this case, the ratio (L1/L2) of the first distance L1 to the second distance L2 is 0.47.

As described above, according to this preferred embodiment (the first configuration and the second configuration), the semiconductor device 1 includes the terminal region 73 of the p-type formed in the second surface portion 9 (the peripheral edge portion of the first principal surface 3) and the source wiring 90 arranged on the second surface portion 9. The first distance L1 between the outer edge 90a of the source wiring 90 and the outer edge 73a of the terminal region 73 is not less than 10 μm. From another point of view, the first distance L1 is not less than the thickness T1 of the second semiconductor region 7 (an epitaxial layer). From another point of view, the ratio (L1/L2) of the first distance L1 to the second distance L2 is not less than 0.1. From still another point of view, the first distance L1 is greater than the third distance L3 between the inner edge 73b of the terminal region 73 and the outer edge 90a of the source wiring 90.

In the outer peripheral region 19, a high electric field is generated in the terminal region 73 where the electric field tends to concentrate. Specifically, in the terminal region 73, a high electric field is locally formed in the high electric field region 74 (see FIG. 19) having a predetermined width from the outer edge 73a of the terminal region 73 toward the first surface portion 8.

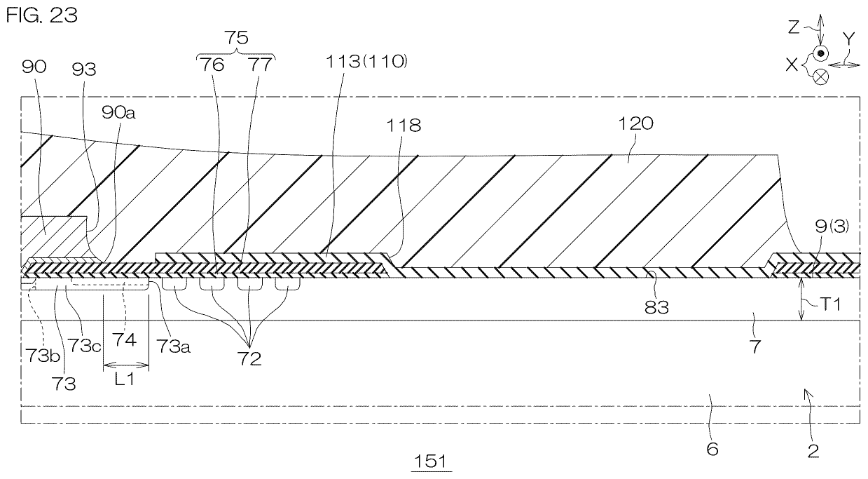

FIG. 23 is a sectional view of a semiconductor device 151 according to a reference embodiment, and is a view corresponding to FIG. 19. When the first distance L1 is set to be short (for example, about 6 μm) as in the semiconductor device 151 according to the reference embodiment shown in FIG. 23, the high electric field region 74 is formed immediately below the source wiring 90, and as a result, there is a risk that a high electric field concentrates on the source wiring 90. In this case, the oxidation reaction of the source wiring 90 may be accelerated.

In contrast, in this preferred embodiment, the first distance L1 is not less than 10 μm. From another point of view, the first distance L1 is not less than the thickness T1 of the second semiconductor region 7 (an epitaxial layer). From another point of view, the ratio (L1/L2) of the first distance L1 to the second distance L2 is not less than 0.1. From still another point of view, the first distance L1 is greater than the third distance L3. Therefore, the high electric field region 74 (see FIG. 19) is formed in a region closer to the peripheral edge side of the first principal surface 3 than the outer edge 90a of the source wiring 90. That is, the electric field region 74 is not formed immediately below the source wiring 90. As a result, the electric field generated in the source wiring 90 can be suppressed low. Since a high electric field is not generated immediately below the source wiring 90, oxidation of the source wiring 90 can be suppressed. As a result, it is possible to suppress the occurrence of a defect caused by oxidation of the source wiring 90.

In addition, since the ratio (L1/L2) of the first distance L1 to the second distance L2 is not more than 0.6, it is possible to suppress an increase in the arrangement ratio of the terminal regions 73 in the first principal surface 3. Therefore, the formation efficiency of the transistor structure Tr on the first principal surface 3 can be increased.

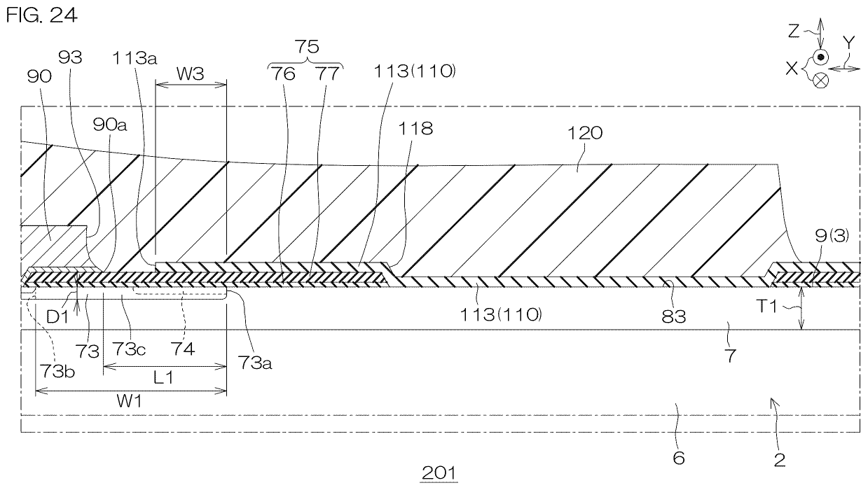

FIG. 24 is a sectional view of a semiconductor device 201 according to another preferred embodiment of the present disclosure, and is a view corresponding to FIG. 19. In FIG. 24, the same components as those described so far are denoted by the same reference numerals, and the description thereof will be omitted.

The semiconductor device 201 according to another preferred embodiment is different from the semiconductor device 1 according to the preferred embodiment shown in FIGS. 1 to 22 in that a plurality of field regions 72 are eliminated. The semiconductor device 201 is not different from the semiconductor device 1 in the other points. According to the semiconductor device 201, operational effects equivalent to the operational effects described in relation to the preferred embodiments shown in FIGS. 1 to 22 are obtained.

Furthermore, in the semiconductor device 201 according to another preferred embodiment, an arrangement in which the first distance L1 is great as in the second configuration example shown in FIG. 22 may be adopted. In other words, in the second configuration example shown in FIG. 22, a plurality of field regions 72 may be eliminated.

In each of the above-described preferred embodiments, the source wiring 90 is the outermost electrode portion, but an arrangement in which the source wiring 90 is eliminated may be adopted. The peripheral edge portion of the source electrode 85 may be an outermost peripheral electrode portion (a peripheral edge source electrode portion). In this case, the distance between the peripheral edge portion (the peripheral edge source electrode portion) of the source electrode 85 and the outer edge 73a of the terminal region 73 can be regarded as the first distance L1. In this case, the distance between the peripheral edge portion (the peripheral edge source electrode portion) of the source electrode 85 and the outer edge 73a of the terminal region 73 is preferably not less than 10 μm.

As a result, the electric field generated in the peripheral edge portion (the peripheral edge source electrode portion) of the source electrode 85 can be suppressed low. Therefore, oxidation of the peripheral edge portion (the peripheral edge source electrode portion) of the source electrode 85 can be suppressed. As a result, it is possible to suppress the occurrence of a defect caused by oxidation of the peripheral edge portion (the peripheral edge source electrode portion) of the source electrode 85.

The respective preferred embodiments of the present invention can be implemented in yet other preferred embodiments. For example, in each of the above-described preferred embodiments, an example in which the mesa 11 (the first surface portion 8, the second surface portion 9, and the first to fourth connecting surface portions 10A to 10D) is demarcated in the first principal surface 3 has been described. However, the first principal surface 3 does not necessarily have to have the mesa 11 and may be formed flatly instead.

In this case, the active region 12 and the outer peripheral region 19 are demarcated by the outer well region 70. In this case, the first end portion region 13, the second end portion region 14, the third end portion region 15, the fourth end portion region 16, the fifth end portion region 17, and the sixth end portion region 18 may be removed.

In each of the above-described preferred embodiments, an example in which the anchor openings 83 are formed in the first inorganic film 75 has been described. However, the first inorganic film 75 not having the anchor openings 83 may be adopted instead.

In each of the above-described preferred embodiments, an example in which the first conductivity type is the n-type and the second conductivity type is the p-type has been described, but the first conductivity type may be the p-type and the second conductivity type may be the n-type. Specific configurations in this case are obtained by replacing the n-type regions with p-type regions and replacing the p-type regions with n-type regions in the description above and the attached drawings.

In each of the above-described preferred embodiments, the chip 2 containing SiC monocrystal is adopted. However, the chip 2 may include a silicon monocrystal instead. Similarly, the first semiconductor region 6 may include a silicon monocrystal. Similarly, the second semiconductor region 7 may include a silicon monocrystal.

In each of the above-described preferred embodiments, a collector region of the p-type may be formed in a surface layer portion of the second principal surface 4 of the chip 2. In this case, the transistor structure Tr includes an IGBT (Insulated Gate Bipolar Transistor) structure in place of the MISFET structure. The specific arrangement in this case is obtained by replacing the “source” of the MISFET structure with an “emitter” of the IGBT structure and replacing the “drain” of the MISFET structure with a “collector” of the IGBT structure in the above description. In this case, the chip 2 may have a single layer structure constituted of a semiconductor substrate of the n-type.

In each of the above-described preferred embodiments, the first semiconductor region 6 (the second semiconductor region 7) may be formed as a portion or a whole of a cathode region of a semiconductor rectifier (a diode) and the body region 20 may be formed as a portion or a whole of an anode region of the semiconductor rectifier (the diode). In this case, the source electrode 85 is formed as an anode electrode and the drain electrode 125 is formed as a cathode electrode. As a matter of course, a Schottky electrode (an anode electrode) forming a Schottky junction with the second semiconductor region 7 may be adopted in place of the body region 20 (the anode region) and the source electrode 85.

Thus, the preferred embodiments of the present disclosure in all respects are illustrative and not to be interpreted to be restrictive and are intended to include modifications in all respects.

The following appended features can be extracted from the descriptions in this Description and the drawings. Hereinafter, the alphanumeric characters, etc., in parentheses represent the corresponding components, etc., in the preferred embodiment described above, but are not intended to limit the scope of each clause to the preferred embodiments.

### [Clause 1-1]

A semiconductor device (1, 201) including:
a chip (2) having a principal surface (3);
a semiconductor region (7) of a first conductivity type formed in a surface layer portion of the principal surface (3);
a device structure (Tr) having a source structure (30) and formed in the semiconductor region (7) at an inner portion of the principal surface (3);
a peripheral edge source electrode portion (90) having a first outer edge (90a), arranged on a peripheral edge portion of the principal surface (3), and electrically connected to the source structure (30); and
a terminal region (73) of a second conductivity type formed in a surface layer portion of the semiconductor region (7) in the peripheral edge portion of the principal surface (3) and electrically connected to the peripheral edge source electrode portion (90), the terminal region (73) including a second outer edge (73a) positioned closer to a peripheral edge side of the principal surface (3) than the first outer edge (90a), in which
a first distance (L1) between the first outer edge (90a) of the peripheral edge source electrode portion (90) and the second outer edge (73a) of the terminal region (73) is not less than 10 μm.

According to this configuration, the semiconductor device (1, 201) includes the terminal region (73) of the second conductivity type formed in the peripheral edge portion of the principal surface (3), and the peripheral edge source electrode portion (90) arranged on the peripheral edge portion of the principal surface (3). The first distance (L1) between the first outer edge (90a) of the peripheral edge source electrode portion (90) and the second outer edge (73a) of the terminal region (73) is not less than 10 μm.

In the peripheral edge portion of the principal surface (3), a high electric field is generated in the terminal region (73). In the terminal region (73), a particularly high electric field is formed in a region (the high electric field region (74)) having a predetermined width from the second outer edge (73a) of the terminal region (73) toward the inner portion of the principal surface (3). Therefore, if the first distance (L1) is set short, the high electric field region (74) is formed immediately below the peripheral edge source electrode portion (90), and as a result, a high electric field may concentrate on the peripheral edge source electrode portion (90). In this case, the oxidation reaction of the peripheral edge source electrode portion (90) may be accelerated.

In contrast, in this arrangement, the first distance (L1) is not less than 10 μm. Therefore, since the high electric field region (74) is not formed immediately below the peripheral edge source electrode portion (90), a high electric field is not generated in the peripheral edge source electrode portion (90). Therefore, oxidation of the peripheral edge source electrode portion (90) can be suppressed. As a result, it is possible to suppress the occurrence of a defect caused by oxidation of the peripheral edge source electrode portion (90).

### [Clause 1-2]

The semiconductor device (1, 201) according to Clause 1-1, wherein the first distance (L1) is not less than a thickness (T1) of the semiconductor region (7).

### [Clause 1-3]

The semiconductor device (1, 201) according to Clause 1-2, wherein the semiconductor region (7) includes an epitaxial layer, and

the first distance (L1) is not less than a thickness (T1) of the epitaxial layer.

### [Clause 1-4]

The semiconductor device (1, 201) according to any one of Clauses 1-1 to 1-3, wherein a ratio (L1/L2) of the first distance (L1) to a second distance (L2) between the first outer edge (90a) of the peripheral edge source electrode portion (90) and a peripheral edge of the principal surface (3) is not less than 0.1 and not more than 0.6.

### [Clause 1-5]

The semiconductor device (1, 201) according to any one of Clauses 1-1 to 1-4, wherein the first distance (L1) is greater than a third distance (L2) between an inner edge (73b) of the terminal region (73) and the first outer edge (90a) of the peripheral edge source electrode portion (90).

### [Clause 1-6]

The semiconductor device (1, 201) according to any one of Clauses 1-1 to 1-5, further including:
a first insulating film (75) covering the terminal region (73) in the principal surface (3); and
a second insulating film (110) arranged on the first insulating film (75) at an interval from the first outer edge (90a) of the peripheral edge source electrode portion (90), wherein

the terminal region (73) includes a covered object portion (73c) that has the second outer edge (73a) and is covered with the second insulating film (110).

### [Clause 1-7]

The semiconductor device (1, 201) according to Clause 1-6, further including a field region (72) of the second conductivity type formed in the surface layer portion of the semiconductor region (7) in a region between the terminal region (73) and the peripheral edge of the principal surface (3), wherein
a first width (W3) of the covered object portion (73c) in the terminal region (73) is not more than a second width (W2) of the field region.

### [Clause 1-8]

The semiconductor device (1, 201) according to Clause 1-6 or 1-7, further including a field region (72) of the second conductivity type formed in the surface layer portion of the semiconductor region (7) in a region between the terminal region (73) and a peripheral edge of the principal surface (3), wherein
a first width (W3) of the covered object portion (73c) in the terminal region (73) is greater than a second width (W2) of the field region.

### [Clause 1-9]

The semiconductor device (1, 201) according to Clause 1-7 or 1-8, wherein the second width (W2) of the field region is less than a third width (W1) of the terminal region (73).

### [Clause 1-10]

The semiconductor device (1, 201) according to any one of Clauses 1-1 to 1-9, in which the chip (2) contains SiC.

### [Clause 1-11]

The semiconductor device (1, 201) according to any one of Clauses 1-1 to 1-10, wherein
the device structure (Tr) includes the source structure (30) of a trench type positioned in the semiconductor region (7), and a well region (36) of the second conductivity type formed in a region along the source structure (30) in the chip (2) and extending along the source structure (30), and
a first depth (D1) of the terminal region (73) is equal to a second depth (DW2) of the well region (36).

### [Clause 1-12]

The semiconductor device (1, 201) according to any one of Clauses 1-1 to 1-11, wherein an impurity concentration of the terminal region (73) is not less than 1.0×10¹⁸ cm⁻³ and not more than 5.0×10²⁰ cm⁻³.

### [Clause 1-13]

The semiconductor device (1, 201) according to any one of Clauses 1-1 to 1-12, wherein the terminal region (73) is formed in the principal surface (3).

### [Clause 1-14]

The semiconductor device (1, 201) according to any one of Clauses 1-1 to 1-13, further including a source electrode (85) arranged on the inner portion of the principal surface (3) and electrically connected to the device structure (Tr), wherein
the peripheral edge source electrode portion (90) includes a source wiring (90) led out from the source electrode (85).

### [Clause 1-15]

The semiconductor device (1, 201) according to any one of Clauses 1-1 to 1-14, wherein the peripheral edge source electrode portion (90) is an outermost peripheral electrode portion in which no other electrode is interposed between the peripheral edge source electrode portion and a peripheral edge of the principal surface (3).

### [Clause 2-1]

A semiconductor device (1, 201) including:
a chip (2) having a principal surface (3);
a semiconductor region (7) of a first conductivity type formed in a surface layer portion of the principal surface (3);
a device structure (Tr) having a source structure (30) and formed in the semiconductor region (7) at an inner portion of the principal surface (3);
a peripheral edge source electrode portion (90) having a first outer edge (90a), arranged on a peripheral edge portion of the principal surface (3), and electrically connected to the source structure (30); and
a terminal region (73) of a second conductivity type formed in a surface layer portion of the semiconductor region (7) at a peripheral edge portion of the principal surface (3) and electrically connected to the peripheral edge source electrode portion (90), the terminal region (73) including a second outer edge (73a) positioned closer to a peripheral edge side of the principal surface (3) than a first outer edge (90a), wherein
a first distance (L1) between the first outer edge (90a) of the peripheral edge source electrode portion (90) and the second outer edge (73a) of the terminal region (73) is not less than a thickness (T1) of the semiconductor region (7).

According to this configuration, the semiconductor device (1, 201) includes the terminal region (73) of the second conductivity type formed in the peripheral edge portion of the principal surface (3), and the peripheral edge source electrode portion (90) arranged on the peripheral edge portion of the principal surface (3). The first distance (L1) between the first outer edge (90a) of the peripheral edge source electrode portion (90) and the second outer edge (73a) of the terminal region (73) is not less than the thickness (T1) of the semiconductor region (7).

### [Clause 2-2]

The semiconductor device (1, 201) according to Clause 2-1, wherein
the semiconductor region (7) includes an epitaxial layer, and
the first distance (L1) is not less than a thickness (T1) of the epitaxial layer.

### [Clause 3-1]

A semiconductor device (1, 201) including:
a chip (2) having a principal surface (3);
a semiconductor region (7) of a first conductivity type formed in a surface layer portion of the principal surface (3);
a device structure (Tr) having a source structure (30) and formed in the semiconductor region (7) at an inner portion of the principal surface (3);
a peripheral edge source electrode portion (90) having a first outer edge (90a), arranged on a peripheral edge portion of the principal surface (3), and electrically connected to the source structure (30); and
a terminal region (73) of a second conductivity type formed in a surface layer portion of the semiconductor region (7) in the peripheral edge portion of the principal surface (3) and electrically connected to the peripheral edge source electrode portion (90), the terminal region (73) including a second outer edge (73a) positioned closer to a peripheral edge side of the principal surface (3) than the first outer edge (90a), wherein
a ratio (L1/L2) of a first distance (L1) between the first outer edge (90a) of the peripheral edge source electrode portion (90) and the second outer edge (73a) of the terminal region (73) to a second distance (L2) between the first outer edge (90a) of the peripheral edge source electrode portion (90) and a peripheral edge of the principal surface (3) is not less than 0.1 and not more than 0.6.

### [Clause 4-1]

A semiconductor device (1, 201) including:
a chip (2) having a principal surface (3);
a semiconductor region (7) of a first conductivity type formed in a surface layer portion of the principal surface (3);
a device structure (Tr) having a source structure (30) and formed in the semiconductor region (7) at an inner portion of the principal surface (3);
a peripheral edge source electrode portion (90) having a first outer edge (90a), arranged on a peripheral edge portion of the principal surface (3), and electrically connected to the source structure (30); and
a terminal region (73) of a second conductivity type formed in a surface layer portion of the semiconductor region (7) in the peripheral edge portion of the principal surface (3) and electrically connected to the peripheral edge source electrode portion (90), the terminal region (73) including a second outer edge (73a) positioned closer to a peripheral edge side of the principal surface (3) than the first outer edge (90a), wherein
a first distance (L1) between the first outer edge (90a) of the peripheral edge source electrode portion (90) and the second outer edge (73a) of the terminal region (73) is greater than a third distance (L3) between an inner edge (73b) of the terminal region (73) and the first outer edge (90a) of the peripheral edge source electrode portion (90).

1. A semiconductor device comprising:
a chip having a principal surface;
a semiconductor region of a first conductivity type formed in a surface layer portion of the principal surface;
a device structure having a source structure and formed in the semiconductor region at an inner portion of the principal surface;
a peripheral edge source electrode portion having a first outer edge, arranged on a peripheral edge portion of the principal surface, and electrically connected to the source structure; and
a terminal region of a second conductivity type formed in a surface layer portion of the semiconductor region in the peripheral edge portion of the principal surface and electrically connected to the peripheral edge source electrode portion, the terminal region including a second outer edge positioned closer to a peripheral edge side of the principal surface than the first outer edge, wherein
a first distance between the first outer edge of the peripheral edge source electrode portion and the second outer edge of the terminal region is not less than 10 μm.

2. The semiconductor device according to claim 1, wherein the first distance is not less than a thickness of the semiconductor region.

3. The semiconductor device according to claim 2, wherein the semiconductor region includes an epitaxial layer, and the first distance is not less than a thickness of the epitaxial layer.

4. The semiconductor device according to claim 1, wherein a ratio of the first distance to a second distance between the first outer edge of the peripheral edge source electrode portion and a peripheral edge of the principal surface is not less than 0.1 and not more than 0.6.

5. The semiconductor device according to claim 1, wherein the first distance is greater than a third distance between an inner edge of the terminal region and the first outer edge of the peripheral edge source electrode portion.

6. The semiconductor device according to claim 1, further comprising:
a first insulating film that covers the terminal region in the principal surface; and
a second insulating film that is arranged on the first insulating film at an interval from the first outer edge of the peripheral edge source electrode portion, wherein the terminal region includes a covered object portion that has the second outer edge and is covered with the second insulating film.

7. The semiconductor device according to claim 6, further comprising a field region of the second conductivity type formed in the surface layer portion of the semiconductor region in a region between the terminal region and a peripheral edge of the principal surface, wherein
a first width of the covered object portion in the terminal region is not more than a second width of the field region.

8. The semiconductor device according to claim 6, further comprising a field region of the second conductivity type formed in the surface layer portion of the semiconductor region in a region between the terminal region and a peripheral edge of the principal surface, wherein
a first width of the covered object portion in the terminal region is greater than a second width of the field region.

9. The semiconductor device according to claim 7, wherein the second width of the field region is less than a third width of the terminal region.

10. The semiconductor device according to claim 1, wherein the chip contains SiC.

11. The semiconductor device according to claim 1, wherein the device structure includes
the source structure of a trench type positioned in the semiconductor region, and a well region of the second conductivity type formed in a region along the source structure in the chip and extending along the source structure, wherein
a first depth of the terminal region is equal to a second depth of the well region.

12. The semiconductor device according to claim 1, wherein an impurity concentration of the terminal region is not less than 1.0×10¹⁸ cm⁻³ and not more than 5.0×10²⁰ cm⁻³.

13. The semiconductor device according to claim 1, wherein the terminal region is formed in the principal surface.

14. The semiconductor device according to claim 1, further comprising a source electrode arranged on the inner portion of the principal surface and electrically connected to the device structure, wherein
the peripheral edge source electrode portion includes a source wiring led out from the source electrode.

15. The semiconductor device according to claim 1, wherein the peripheral edge source electrode portion is an outermost peripheral electrode portion in which no other electrode is interposed between the peripheral edge source electrode portion and a peripheral edge of the principal surface.
